(19) United States
(12) Patent Application Publication
(10) Pub. No.: US 2024/0365513 A1
(43) Pub. Date: Oct. 31, 2024

(54) OPTIMIZED AND AUTOMATED DYNAMIC THERMAL REGULATION METHOD AND APPARATUS WITH SELF-TUNING TWO-PHASE COOLING SYSTEM

(71) Applicant: Intel Corporation, Santa Clara, CA (US)

(72) Inventors: Prabhakar SUBRAHMANYAM, San Jose, CA (US); Ying-Feng PANG, San Jose, CA (US); Vishnu Prasadh SUGUMAR, Santa Clara, CA (US)

(21) Appl. No.: 18/394,503

(22) Filed: Dec. 22, 2023

(51) Int. Cl. H05K 7/20; F25B 5/02; F25B 49/02; G06F 1/20

(52) U.S. Cl. CPC H05K 7/20381; F25B 5/02; F25B 49/022; G06F 1/206; H05K 7/20309; H05K 7/20327; F25B 2700/191; F25B 2700/197; F25B 2700/2108; F25B 2700/21174; F25B 2700/21175

(57) ABSTRACT

An apparatus and method for cooling a computing system, comprising a plurality of electronic components, with a cooling system. The cooling system includes a closed loop for the two-phase coolant, wherein the two-phase coolant has a saturation temperature. The closed loop includes a valve fluidly connected between an outlet of a heat exchanger and an inlet of a plurality of evaporator structures configured to be thermally coupled to the plurality of electronic components, and a compressor fluidly connected between an outlet of the plurality of evaporator structures and an inlet of the heat exchanger. The apparatus and method for the cooling system are configured to monitor one or more system temperatures of the computing system and adjust an operation of at least one of the valve or the compressor to alter the saturation temperature based on the one or more system temperatures.

### BACKGROUND

Thermal design power for personal computing systems, such as desktop computers, is constantly increasing, particularly with the wide adoption of gaming, scientific computing, video editing, and other intensive processing applications. Computing systems that are fit for these purposes are becoming power-hungry, with multiple processing units (“XPUs” such as central processing units (CPUs), graphical processing units (GPUs), or data processing units (DPUs)) and memory modules (such as Dual In-Line Memory Modules (DIMMs)). The total power dissipation of a fully loaded system may total up to 1 kW. Users, such as gamers and researchers, are turning to liquid cooling in a closed-loop environment (heat exchangers with cold plates) to cool the CPU, GPU, and other high-power dissipating devices inside the computer. However, the ambient temperature often gets increasingly hotter with gaming enthusiasts and computing app user community overclocking the CPU and operating the silicon close to the maximum safe operating temperature for a processing unit (Tjmax) and running into silicon thermal throttling issues degrading the performance of the CPU. Power density may also be so high that traditional air cooling or closed-loop heat exchanger liquid cooling is unable to remove the heat loads effectively from these extended power levels.

Therefore, an improved concept for colling high-power dissipating devices in a computer system may be desired. In particular, the following disclosure describes a self-optimizing, tunable, two-phase, eco-friendly cooling system and process for simultaneously cooling a CPU, GPU, DIMMs, and other high-power dissipating devices.

### BRIEF DESCRIPTION OF THE FIGURES

Some examples of apparatuses and/or methods will be described in the following by way of example only, and with reference to the accompanying figures, in which

FIGS. 1A and 1B show schematic diagrams for a two-phase cooling system for a computing system;

FIG. 2 shows an example of a closed-loop, single-phase liquid liquid-assisted air cooling system;

FIG. 3 shows a diagram of a method for regulating a two-phase cooling system;

FIG. 4 shows a diagram of an algorithm for regulating a two-phase cooling system;

FIG. 5A shows a visualization of a two-phase cooling system for a desktop chassis;

FIGS. 5B and 5C show visualizations of a two-phase cooling system within a desktop chassis;

FIG. 6 shows a diagram of a two-phase cooling system with a graph of the thermodynamic state point of the vapor compression cycle;

FIG. 7 shows a visualization of a two-phase cooling system with connections to a processor;

FIGS. 8A and 8B show visualizations of a two-phase cooling system with a connection to an interface;

FIG. 9 shows a visualization of a two-phase cooling system with pressure transducer connections;

FIG. 10 shows a graph of experimental data for a compressor of a two-phase cooling system;

FIG. 11 shows waking up the server and sleep the worker in accordance with one example; and

FIG. 12 is a block diagram of an electronic apparatus incorporating at least one electronic assembly and/or method described herein.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures, same or similar reference numerals refer to same or similar elements and/or features, which may be identical or implemented in a modified form while providing the same or a similar function. The thickness of lines, layers, and/or areas in the figures may also be exaggerated for clarification.

When two elements A and B are combined using an “or,” this is to be understood as disclosing all possible combinations, i.e., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a,” “an,” and “the” are used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise,” and/or “comprising,” when used, describe the presence of the specified features, integers, steps, operations, processes, elements, components, and/or a group thereof, but do not exclude the presence or addition of one or more other features, integers, steps, operations, processes, elements, components and/or a group thereof.

In the following description, specific details are set forth, but examples of the technologies described herein may be practiced without these specific details. Well-known circuits, structures, and techniques have not been shown in detail to avoid obscuring an understanding of this description. “An example/example,” “various examples/examples,” “some examples/examples,” and the like may include features, structures, or characteristics, but not every example necessarily includes the particular features, structures, or characteristics.

Some examples may have some, all, or none of the features described for other examples. “First,” “second,” “third,” and the like describe a common element and indicate different instances of like elements being referred to. Such adjectives do not imply element item so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform, or resource, even though the instructions contained in the software or firmware are not actively being executed by the system, device, platform, or resource.

The description may use the phrases “in an example/example,” “in examples/examples,” “in some examples/examples,” and/or “in various examples/examples,” each of which may refer to one or more of the same or different examples. Furthermore, the terms “comprising,” “including,” “having,” and the like, as used with respect to examples of the present disclosure, are synonymous.

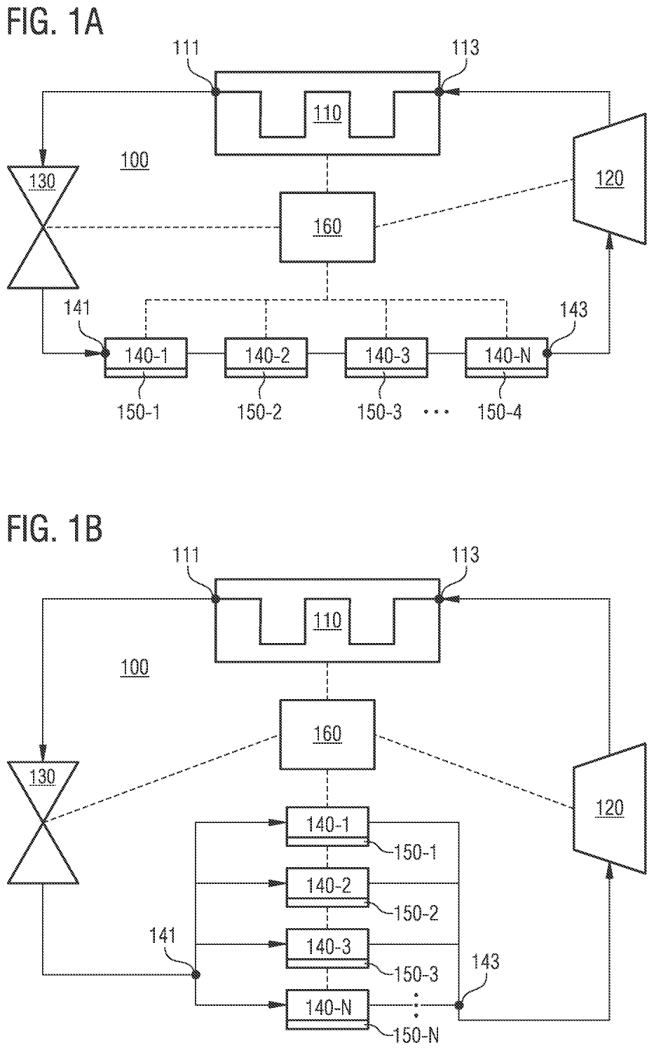

FIGS. 1A and 1B show schematic diagrams for a two-phase cooling system for a computing system. A cooling system 100 for a computing system may comprise a plurality of electronic components 150-1 . . . 150-N. The cooling system further comprises a two-phase coolant having a saturation temperature and a closed loop 110 for the two-phase coolant. The closed loop may comprise a valve 130 fluidly connected between an outlet 111 of a heat exchanger 110 and an inlet 141 of a plurality of evaporator structures 140-1 . . . 140-N configured to be thermally coupled to the plurality of electronic components 150-1 . . . 150-N. The closed loop may further comprise a compressor 120 fluidly connected between an outlet 143 of the plurality of evaporator structures 140-1 . . . 140-N and an inlet 113 of the heat exchanger 100. The cooling system 100 may comprise processing circuitry 160, wherein the processing circuitry is configured to monitor one or more system temperatures of the computing system and adjusts an operation of at least one of the valve 130 or the compressor 120 to alter the saturation temperature based on the one or more system temperatures.

The evaporator structures may be cold plates. An evaporator is a heat exchange component in a refrigeration or cooling system that facilitates the phase change of a liquid refrigerant into a vapor. During this phase change, heat from the surroundings or a heat source is absorbed, resulting in cooling or heat removal. Evaporators are commonly used in air conditioning, refrigeration, and heat pump systems to provide cooling or refrigeration by removing thermal energy from the area or object being cooled.

The evaporator structures may include cold plates with microchannel designs, integrated wicking materials for efficient fluid distribution, and multi-layered configurations for enhanced heat dissipation. These evaporator structures efficiently transfer heat from heat sources, such as electronic components, to a circulating cooling fluid within a closed-loop system, thereby optimizing thermal management and maintaining consistent operating temperatures.

Electronic components may any hardware elements within a computing or other system that are integral to its electronic functions. These components are typically characterized by their active involvement in the processing, storage, or transmission of electronic signals or energy, often generating heat as a byproduct of their operation. Given the susceptibility of these components to performance degradation or failure when subjected to excessive thermal conditions, they are generally candidates for thermal regulation or cooling solutions. It is understood that the enumeration of such electronic components is illustrative and not exhaustive, acknowledging the continual evolution of computing technology.

Such components may include a central processing unit (CPU), graphics processing unit (GPU), memory modules (e.g., RAM), motherboard chipsets, power supply units (PSU), batteries, hard disk drives (HDD) and solid-state frives (SSD), network interface cards (NIC), voltage regulator modules (VRM), optical drives, sound cards, expansion cards (e.g., PCIe cards), input/output (I/O) controllers, capacitors and transistors involved in power regulation and distribution, integrated circuits (ICs) such as BIOS/UEFI chips, cooling system components themselves (e.g., liquid cooling pumps). The cooling system may be applied outside of a computing environment. For instance, this system can be easily adopted for use in electric vehicles to cool a multitude of batteries and other heat producing electronics that are non-computing in nature. Since the operation is also quieter without noise and eco-friendly with two phase coolant, it can be easily adopted.

Thermal design power for personal computing systems, such as desktop computers, is constantly increasing, particularly with the wide adoption of gaming, scientific computing, video editing, and other intensive processing applications. Computing systems that are fit for these purposes are becoming power-hungry, with multiple processing units (“XPUs” such as central processing units (CPUs), graphical processing units (GPUs), or data processing units (DPUs)) and memory modules (such as Dual In-Line Memory Modules (DIMMs)). The total power dissipation of a fully loaded system may total up to 1 kW. Users, such as gamers and researchers, are turning to liquid cooling in a closed-loop environment (heat exchangers with cold plates) to cool the CPU, GPU, and other high-power dissipating devices inside the computer. However, the ambient temperature often gets increasingly hotter with gaming enthusiasts and computing app user community overclocking the CPU and operating the silicon close to the maximum safe operating temperature for a processing unit (Tjmax) and running into silicon thermal throttling issues degrading the performance of the CPU. Power density may also be so high that traditional air cooling or closed loop heat exchanger liquid cooling is unable to remove the heat loads effectively from these extended power levels (PL2, PL3, CPU+GPU combination, etc. . . . ).

The system 100 of FIGS. 1A and 1B provides for an advanced autonomous two-phase tunable compressor cooling apparatus with an adaptive control algorithm for cooling CPU, GPU, DIMMs, and other electronic devices. Installation of this system into desktops or other computing devices may increase their eco-friendliness and performance.

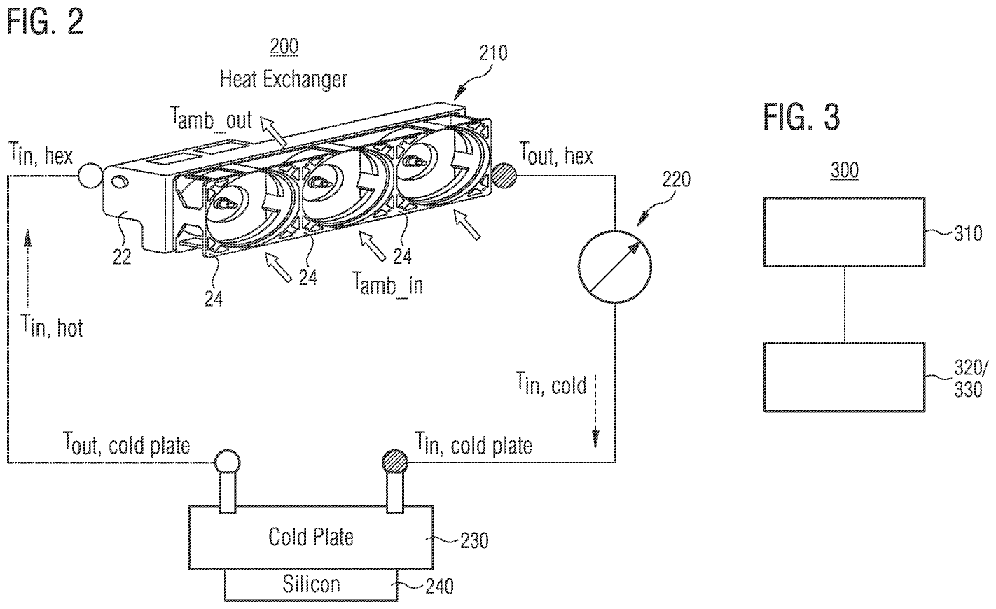

FIG. 2 shows a known example of a closed-loop, single-phase liquid-assisted air cooling system. Specifically, FIG. 2 shows a closed-looped, liquid-assisted, air-cooled (LAAC) solution where cold plate 230 connected to a heat exchanger 210 is employed independently on each processor 240 to dump the heat to the ambient environment.

The system 200 has a heat exchanger (“hex”) 210, which is designed to transfer heat between a working fluid (liquid or gas) and the ambient air. Working fluids, also called a heat-transfer fluid, are pumped, or otherwise forced (with a pump or compressor 220) through a heat sink 230, often consisting of a metal block or plate (also called a cold plate), that makes direct contact with the heat-producing component 240, such as the CPU or GPU. The working fluid is then pumped to the heat exchanger 210. Heat exchangers in computer systems generally comprise a heat exchanger core 212 (such as a radiator), and one or more fans 214 mounted on it. The core 212 is often made of metal with a network of tubes for the working fluid to pass through and fins to increase the surface area for efficient heat dissipation. The fans 214 blow air over the core 212, helping to transfer heat away from working fluid and maintain safe operating temperatures for the computer system.

The working fluid enters the heat exchanger 210 at a higher temperature 211 (T_{in,hex}) and exits, in principle, at a lower temperature (T_{out,hex}) due to the transfer of its heat with the ambient air. Conversely, air enters the heat exchanger 210 at an ambient temperature (T_{amb_in}) and exits at an increased ambient temperature (T_{amb_out}) due to the heat transfer process with the working fluid. The working fluid is then pumped through one or more heat sinks or cold plates 230 where heat from computing components 240 is transferred to the working fluid. So long as the working fluid can absorb heat, each component 240 increases the temperature of the working fluid from a local lower temperature (T_{in,cold plate}) to a higher temperature (T_{out,cold plate}). Likewise, with multiple components 240, the whole system should increase the working fluids temperature from a cold temperature (T_{in, cold}) substantially equal to the exit temperature (T_{out,hex}) from the heat exchanger to a hot temperature (T_{in,hot}) substantially equal to the entering temperature to the heat exchanger (T_{in,hex}), where the cycle repeats.

Working fluids are often in a single-phase (single state), either liquid or gas, at the given temperature and pressure conditions. Water, for example, is typically a single-phase fluid when it's in its liquid state. However, in some embodiments it may be used as a two-phase (as a liquid or gas, for example) fluid. In many heat exchanger systems, single-phase fluids are used for heat transfer, especially in applications with moderate temperature ranges.

A working fluid in a heat exchanger system may not lose heat to the increased ambient air temperature because heat transfer depends on the temperature difference between the fluid and the surroundings. In a heat exchanger, heat naturally flows from a region of higher temperature to a region of lower temperature. If the working fluid's temperature remains higher than the ambient air temperature, it will continue to release heat into the cooler air, even if the air temperature increases slightly. Generally, as long as the fluid's temperature remains higher than the ambient air, there will still be a net flow of heat from the fluid to the air.

However, the rate of heat transfer may decrease as the temperature difference decreases. This may occur as processors or other heat-dissipating components get hot inside the chassis of the computer system. Thus, the thermal dissipative capability of an LAAC solution, such as in FIG. 2, may be fixed because of increasing ambient temperature and depending on the efficiency of the heat exchanger. Moreover, the efficiency of this and other single-phase thermal solutions often cannot be either scaled down or scaled up. Meaning that it cannot easily adapt to changing thermal conditions or operate at peak energy efficiency, potentially leading to energy waste or reduced heat transfer rates.

The remaining figures and examples herein describe a microcontroller-driven automated approach to two-phase cooling, featuring a pressure-regulated, miniaturized tunable compressor system. The apparatus and method may simultaneously cool a CPU, GPU, and Memory DIMMs to achieve a seamless and homogenous cooling solution. This may be accomplished through the integration of cold plates onto all the electronic devices 150-1 . . . 150-N (XPUs) in a closed-loop configuration.

The computer system may be a client device. A client device, in the context of computing, may refer to a user-oriented computing system such as a desktop computer, laptop, tablet, or other personal computing device. These devices are designed to accommodate a wide range of computing tasks and user interactions, and they typically operate under variable workloads, adapting to the specific needs and demands of individual users. Client devices serve as endpoints in various computing environments, connecting users to networks, cloud services, and data resources, and they are characterized by their versatility, responsiveness, and ability to handle diverse applications and workloads, from web browsing and document editing to gaming and multimedia content consumption.

The computer system may comprise a maximum power dissipation of 1 kW. This system may be capable of efficiently cooling systems with a thermal load of up to 1 kilowatt (KW) or up to 2 kW or 10 kW or 100 kW or greater. The system may offer a lightweight design, provide high isentropic efficiency, and operate silently. This may make the system ideal for integration into a desktop form factor and allow the form factor to cool thermal loads that are significantly increased compared to conventional cooling designs.

Two-phase fluids, compared to the single-phase fluid of FIG. 2, may consist of both liquid and gas phases simultaneously. This occurs when the fluid is near its boiling or condensing point. For instance, in a refrigeration system, the two-phase coolant (a refrigerant) may transition between liquid and vapor phases as it absorbs and releases heat. This phase change is critical for many cooling and refrigeration processes.

The plurality of evaporator structures 140-1 . . . 140-N may be fluidly in series as shown in FIG. 1A or in parallel as shown in FIG. 1B. In single-phase embodiments, such as FIG. 2, CPUs, GPUs, and memory components often require independent thermal solutions. Single-phase, closed-loop cold plates or air-cooling heat sink solutions such as in FIG. 2 are typically employed inside a closed chassis desktop environment. However, single-phase, closed-loop cold plates or air cooling solutions are unable to remove excessive heat loads dictated by gaming enthusiasts or overclocking computational experts who push the silicon to higher power levels. Higher ambient temperature inside the desktop results in higher temperature inside the condenser in closed loop heat exchanger with cold plates resulting in higher heat loads on the CPU which is undesirable for overclocking enthusiasts. Memory DIMMs in sing-phase systems are typically air-cooled and operate at higher than desirable temperatures.

A two-phase cooling system works on the principle of latent heat of vaporization which enables cold plates for multiple XPUs to be connected in series or parallel. These benefits have only previously been explored and used in specialized applications like high-performance computing clusters and data centers because of their perceived complexity.

A two-phase coolant is a type of cooling fluid that can exist in both liquid and vapor phases within a closed system, and it undergoes phase changes (evaporation and condensation) during the cooling process. These coolants are commonly used in various cooling systems to efficiently transfer heat by changing phase, which makes them effective for applications like refrigeration, air conditioning, and electronics cooling.

Water is one of the most common and effective two-phase coolants due to its readily accessible phase change characteristics. However, many other two-phase coolants or refrigerants have been found effective in a computing environment. The processor may adjust the valve and/or the compressor based on thermodynamic information for the two-phase coolant. R-1234ze is a refrigerant known by its chemical name 1,3,3,3-tetrafluoropropene. It is considered a hydrofluoroolefin (HFO) refrigerant and is part of the HFO family, which is known for having a lower global warming potential (GWP) compared to traditional hydrofluorocarbon (HFC) refrigerants.

R-1234ze is commonly used as a replacement for R-134a, which is a high-GWP refrigerant often found in air conditioning and refrigeration systems. R-1234ze has a significantly lower GWP, making it more environmentally friendly and compliant with regulations aimed at reducing greenhouse gas emissions.

R-1234ze exists in both gas and liquid phases within a refrigeration cycle, making it a two-phase coolant. During the refrigeration process, it undergoes phase changes from a gas to a liquid (condensation) and from a liquid to a gas (evaporation) to transfer heat and maintain temperature control in various cooling applications, including air conditioning systems and refrigeration equipment.

The use of R-1234ze and other low-GWP refrigerants may reduce the environmental impact of cooling and refrigeration systems and mitigate climate change by decreasing the release of high-GWP gases into the atmosphere. Examples of other two-phase other coolants, include R-134a, R-744 (Carbon Dioxide, CO2), R-410A, R-32, Ammonia (NH3), R-290 (Propane), R-1234yf, and R-1233zd.

A two-phase coolant may be a low-GWP refrigerant. A compressor and other components of the cooling system may be designed for the proper handling of eco-friendly refrigerants. Some low-GWP refrigerants may be corrosive, flammable, or toxic. Therefore it is important to use them in a system that properly handles their properties. For example, the autonomous tunable device may include a completely closed loop with fully brazed components. This provides a leak-free and emissions-free performance to avoid any harmful effects from the coolant. It also allows for a safe, environment-friendly, self-contained thermal solution in an adequately packaged form factor. All or parts of the system, such as the closed loop and compressor, may include compatible materials to prevent corrosion and leakage, compatibility with specialized lubricants, the ability to handle different pressure and temperature ranges, optimal energy efficiency, leak prevention mechanisms, safety measures like pressure relief valves, adherence to environmental regulations, adaptability to various eco-friendly refrigerants, reliability, and case of serviceability. For example, a cooling system for a low-GWP coolant may incorporate materials (such as stainless steel, copper, aluminum, similar metals, and alloys thereof) that are more compatible to prevent corrosion and leaks that may not be necessary due to the different chemical composition of high-GWP coolants. The compressor or other components materials may be coated with corrosion-resistant coatings or anodized to increase their compatibility with low-GWP refrigerants. These design considerations are crucial for reducing environmental impact, minimizing greenhouse gas emissions, and complying with evolving environmental standards while maintaining effective refrigeration and cooling processes.

A processor adjusts the valve and/or the compressor based on thermodynamic information for the two-phase coolant. The microcontroller unit may be programmed with multiple coolant or refrigerant data as well as specifications on various compressors so that it can calculate the entire phase change thermodynamic calculations for the refrigerant working fluid in the compressor based on a required set point temperature requested by the user or autonomously as calculated by the microcontroller when it reads a certain Tj from the main motherboard. Higher Tj will get a lower Tsat (for high heat dissipating capability) and a lower Tj will get a higher Tsat by controlling the pressure knob. The coolant saturation temperature should be optimized for power being cooled.

The saturation temperature of a coolant refers to the specific temperature at which a coolant (typically a liquid) changes phase to a gas at a given pressure. This temperature is critical in thermodynamic processes, particularly in cooling systems, as it marks the boundary where the coolant begins to boil and vaporize. In a closed system, the saturation temperature depends on the pressure within the system; higher pressures will raise the saturation temperature and lower pressures will reduce it. This property of coolants is utilized in various applications, including air conditioning, refrigeration, and liquid cooling systems for electronics, where the phase change from liquid to vapor can absorb a significant amount of heat, aiding in effective temperature regulation of the system. It is important that a processor has access to information on saturation temperature in order to operate a cooling systems efficiently. Ensuring that the coolant operates within its optimal thermal and pressure range may prevent overheating or system failure.

Two-phase coolants are chosen based on their specific properties, environmental impact, and compatibility with the intended application. The selection of a coolant depends on factors such as system efficiency, safety, and regulatory requirements, therefore a microcontroller should have access to thermodynamic information on several coolants

If a coolant is unknown to the processor, the processor may be able to obtain information from the local computing system, network, Internet, or user on the coolant. The processor may determine some or all of the thermodynamic information for the two-phase coolant using its control over the valve and compressor as well as from readings from temperature and pressure sensors. For example, if two coolants are mixed, such as if R-1234ze is mixed with water, the processor may be able to adjust the known saturation temperatures to adjust for the water or determine all new saturation temperatures for the combined or novel coolant.

The system may further comprise a memory in communication with the processor, wherein the memory stores the thermodynamic information for the two-phase coolant. This allows for the storing of existing thermodynamic information for known coolants, the updating of thermodynamic information for new coolants, determined thermodynamic information, readings from temperature and pressure sensors, diagnostic data, performance data, and other data either obtained or generated by the processor.

High-performance computing clusters (data centers, servers, etc.) utilizing a two-phase cooling system typically run their compressors at full blast to cool electronics and do not have an efficient control algorithm to appropriately modulate the speed. Running the compressor at full blast may be advantageous due to the consistently high utilization of these systems, ensuring optimal cooling capacity and temperature control for sustained, demanding workloads. In contrast, for a desktop computer or other systems with less consistent utilization, a tunable compressor provides flexibility to adjust the cooling intensity, making it more beneficial as it can efficiently manage variable workloads and maintain quieter operations during less demanding tasks.

In particular, when higher power (PL2, overclocking, etc.) is used by workloads or apps on a variable load system, a microcontroller or processor 160 may read the rise in junction temperatures (Tj) and case temperatures (Tcase) via temperature sensors and regulates or adjusts the pressure in the compressor to a higher saturation temperature (Tsat) of the refrigerant. When the power drops to a regular thermal design power (TDP) scenario, the microcontroller reads the temperature drop and adjusts the pressure to output a lower refrigerant Tsat. This processes is autonomous and dynamic in a closed-loop system. This system may be robust and provide a seamless user experience for gaming users and high-performance (overclocking) desktop users alike. Additionally, implementing a variable, tunable cooling system may offer environmental benefits by optimizing energy efficiency, reducing power consumption, and lowering greenhouse gas emissions. Thus contributing to an eco-friendlier cooling system.

Implementing an efficient control algorithm in a microcontroller may also monitor the pressure data from the pressure transducers to reach the desired set point temperature, calculate the required mass flow rate (mdot) required by the compressor to reach the desired saturation temperature, and instruct the compressor to operate at an interpolated revolutions per minute (RPM) from the compressor data so that the compressor always runs at an efficient speed and not at full blast.

Implementing an efficient control algorithm for a two-phase tunable compressor in a desktop, personal, or other client-focused computing system may increase the cooling ability of the system while making the whole cooling procedure autonomous in nature with zero emissions to the environment.

The system 100 may father comprise an LCD panel (such as in the desktop chassis) with switches to increase or decrease the set point temperature (Tset). The LCD panel may be presented to a user as an ad-hoc option to manually increase (in case of potential overclocking) or decrease the Tset once gaming is done. The processor may then adjust the valve and/or the compressor based on input from the external interface. A temperature set by the user might not be determinative if the processor determines that other factors are more critical to the health or efficiency of the system and the electronic components.

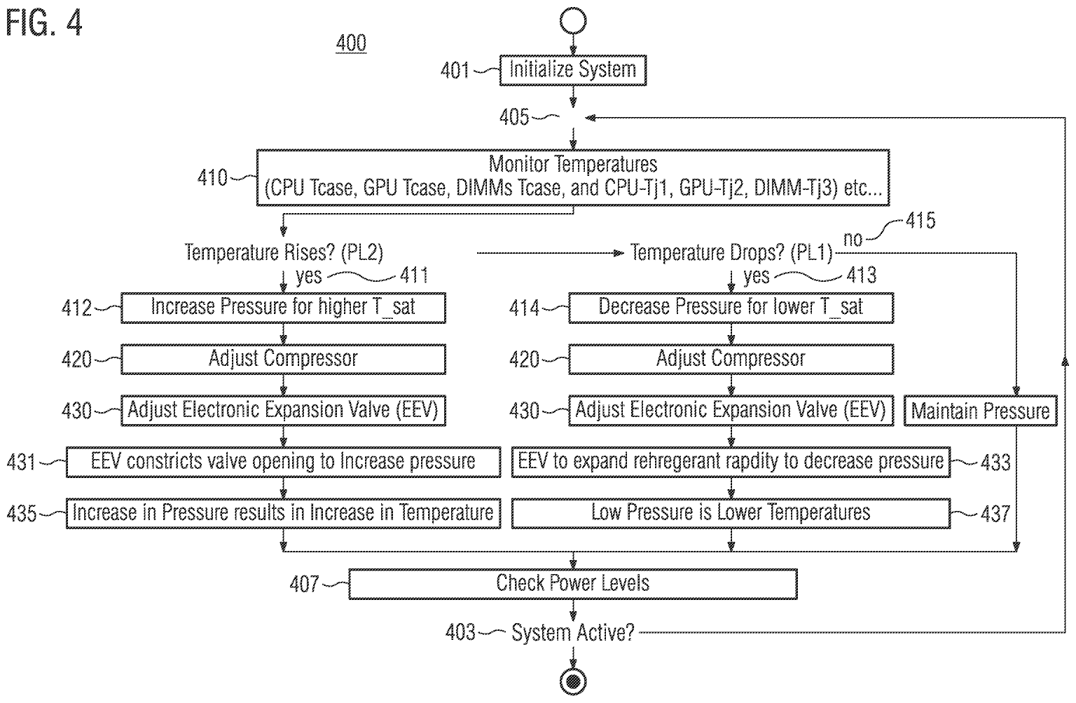

More details and optional aspects of FIGS. 1A and 1B may be described in connection with examples described below (e.g. FIGS. 3 to 12).

FIG. 3 shows a diagram of a method 300 for regulating a two-phase cooling system. The method 300 may comprise monitoring 310 one or more system temperatures and adjusting a valve 330 and/or a compressor 320 to alter the saturation temperature based on one or more system temperatures. The cooling system may comprise a two-phase coolant having a saturation temperature and a closed loop for the two-phase coolant. The closed loop may comprise the valve fluidly connected between an outlet of a heat exchanger and an inlet of a plurality of evaporator structures, wherein each of the plurality of evaporator structures is thermally coupled with the plurality of electronic components. The closed loop may further comprise the compressor fluidly connected between an outlet of the plurality of evaporator structures and an inlet of the heat exchanger.

Examples may further be or relate to a (computer) program including a program code to execute one or more of the above methods when the program is executed on a computer, processor, or other programmable hardware component. Thus, steps, operations, or processes of different ones of the methods described above may also be executed by programmed computers, processors, or other programmable hardware components. Examples may also cover program storage devices, such as digital data storage media and non-transitory mediums, which are machine-, processor- or computer-readable and encode and/or contain machine-executable, processor-executable, or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

A non-transitory, computer-readable medium may comprise a program code that, when the program code is executed on a processor, a computer, or a programmable hardware component, causes the processor, computer, or programmable hardware component to perform the method 300.

Below is MATLAB code that will automatically fetch the required set point pressure for the set point saturation temperature required. Specifically, it is an example microcontroller algorithm that will calculate the desired pressure set point required to set in the compressor to achieve a desired saturation temperature for the refrigerant R-1234ze. Given the saturation temperature (Tsat) set point, the microcontroller will automatically extract the desired pressure set point to be set at the compressor valve control.

```
  % Define the Thermodynamic properties of the refrigerant R-1234ze
  % Temperature (F)
  % Pressure (psia)
  % Density Liquid (lb/ft\hat{ }3)
  % Density Vapor (lb/ft\hat{ }3)
  % Enthalpy Liquid (Btu/lb)
  % Enthalpy Vapor (Btu/lb)
  % Entropy Liquid (Btu-R-lb)
  % Entropy Vapor (Btu-R-lb)
  temperature_data = [−40 −35, −30, −25, −20, −15, −10, −5, 0, 5, 10, 15, 20, 25, 30, 35, 40,
45, 50, 55, 60, 65, 70, 75, 80, 85, 90, 95, 100, 105, 110, 115, 120, 125, 130, 135, 140, 145, 150];
  pressure_data = [5.3, 6.2, 7.1, 8.2, 9.3, 10.7, 12.1, 13.7, 15.5, 17.4, 19.5, 21.9, 24.4,
27.2, 30.1, 33.4, 36.9, 40.7, 44.7, 49.1, 53.8, 58.8, 64.2, 69.9, 76.0, 82.5, 89.4, 96.8, 105, 113,
122, 131, 141, 151, 162, 173, 185, 198, 211];
  density_liquid_data = [84.25, 83.79];
  density_vapor_data = [ ];
  enthalpy_liquid_data = [ ];
  enthalpy_vapor_data = [ ];
  entropy_liquid_data = [ ];
  entropy_vapor_data = [ ];
  % Prompt the user for the desired saturation temperature
  clc % clear the screen to reduce clutter shown
  desired_temperature = input(‘Enter the desired saturation temperature in °F: ’);
  % Calculate the desired pressure setpoint
  desired_pressure = interpolatePressure(desired_temperature, temperature_data,
pressure_data);
  % Check if the desired temperature is within the given range
  if ~isnan(desired_pressure)
    fprintf(‘For a desired saturation temperature of %d °F, the desired pressure setpoint is
%.2f psia.\n’, desired_temperature, desired_pressure);
  else
    disp(‘Desired temperature is out of the provided data range.’);
  end
  % Function to interpolate pressure
  function pressure = interpolatePressure(temperature, temperature_data, pressure_data)
    for i = 1:(length(temperature_data) − 1)
      if temperature_data(i) <= temperature && temperature <= temperature_data(i + 1)
        t1 = temperature_data(i);
        t2 = temperature_data(i + 1);
        p1 = pressure_data(i);
        p2 = pressure_data(i + 1);
        pressure = p1 + (p2 − p1) * (temperature − t1) / (t2 − t1);
        return;
      end
    end
    pressure = NaN; % If the desired temperature is out of range
  end
```

It is further understood that the disclosure of several steps, processes, operations, or functions disclosed in the description or claims shall not be construed to imply that these operations are necessarily dependent on the order described unless explicitly stated in the individual case or necessary for technical reasons. Therefore, the previous description does not limit the execution of several steps or functions to a certain order. Furthermore, in further examples, a single step, function, process, or operation may include and/or be broken up into several sub-steps, -functions, -processes, or -operations.

If some aspects have been described in relation to a device or system, these aspects should also be understood as a description of the corresponding method. For example, a block, device, or functional aspect of the device or system may correspond to a feature, such as a method step, of the corresponding method. Accordingly, aspects described in relation to a method shall also be understood as a description of a corresponding block, a corresponding element, a property, or a functional feature of a corresponding device or a corresponding system.

As used herein, the term “module” refers to logic that may be implemented in a hardware component or device, software or firmware running on a processing unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processing units, state machine circuitry, and/or firmware that stores instructions executable by programmable circuitry. Modules described herein may, collectively or individually, be embodied as circuitry that forms a part of a computing system. Thus, any of the modules can be implemented as circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processing units capable of executing computer-executable instructions to perform any of the disclosed methods. As used herein, the term “computer” refers to any computing system or device described or mentioned herein. Thus, the term “computer-executable instruction” refers to instructions that can be executed by any computing system or device described or mentioned herein.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based examples (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

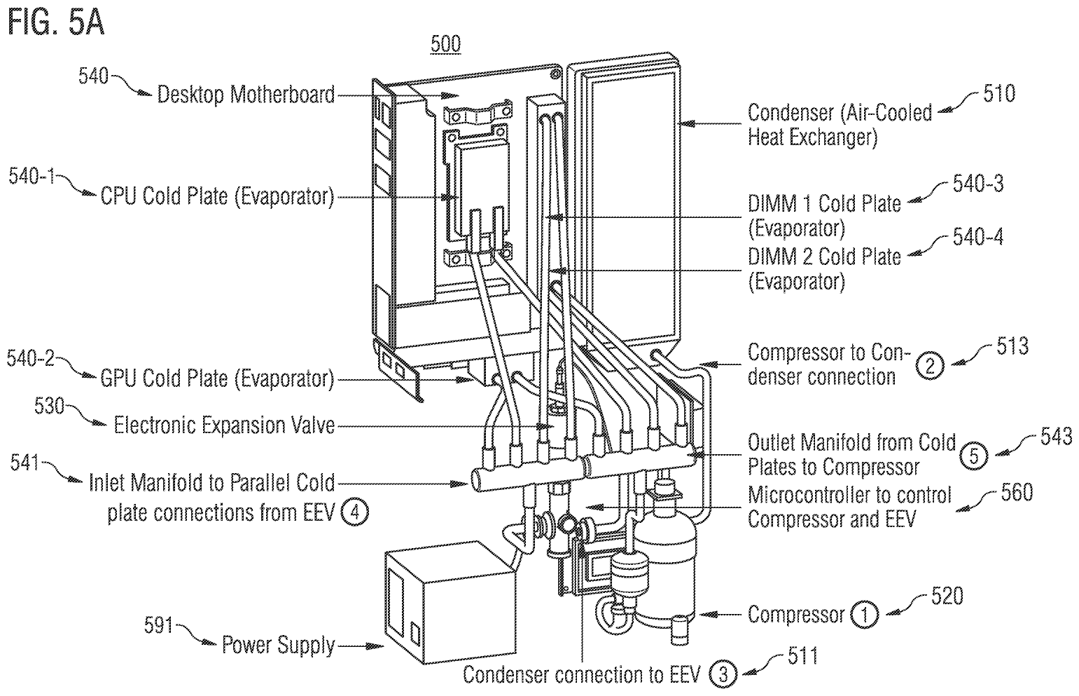

More details and optional aspects of FIG. 3 may be described in connection with examples described above (e.g. FIGS. 1A and 1B) or below (e.g. FIGS. 4 to 12).

FIG. 4 shows a diagram of an algorithm for regulating a two-phase cooling system. A method may be formulated as a dynamic closed-loop algorithm 400 to regulate pressure to increase or decrease saturation temperatures (Tsat). Specifically, the flow chart of FIG. 4 shows a feedback adaptive method or control algorithm that calculates the required pressure setpoint based on the desired saturation temperature. The algorithm may factor into account the specific refrigeration cycle/data used in the system (such as a vapor compression cycle, the Tj and Tcase temperatures of all the cold plates, compressor critical temperature, and the condenser threshold temperatures) The algorithm also fine tunes/controls the compressor and the expansion valve to affect the Tsat change within the system.

In a closed-loop refrigerant system, a higher saturation temperature (Tsat) generally increases the heat dissipation capacity. The Tsat represents the temperature at which the refrigerant changes its phase from a liquid to a vapor within the evaporator (cold plate). When the saturation temperature increases, the temperature at which the refrigerant begins to evaporate is essentially raised. This means that the refrigerant can absorb more heat energy from the surroundings before reaching its boiling point. As a result, the system can dissipate more heat and provide better cooling capacity.

Compressor-driven cooling systems may be more energy-efficient because they can recapture some of the energy from the vapor phase and use it to compress the refrigerant, improving overall cooling efficiency. To control the pressure and, consequently, regulate the saturation temperature of a refrigerant like R-134a, R-1234ze, or another refrigerant coolant, a refrigeration system with a compressor and a pressure control mechanism is typically required.

The method or algorithm 400 may first initialize the system 401. The algorithm may then monitor 410 a plurality of system temperatures. These may include a CPU Tcase, GPU Tcase, DIMMs Tcase, and CPU-Tj1, GPU-Tj2, DIMM-Tj3 etc.

A Tcase temperature is usually measured on the external surface of the device and is a useful metric for understanding the temperature at which the device's packaging can safely operate. It is typically monitored by a motherboard or system monitoring software to ensure that devices, like the CPU, remain within safe temperature limits. Tcase temperatures (such as CPU Tcase) are generally lower than the actual core temperatures (such as CPU-Tj1), as they measure the temperature of the CPU package, not the actual processor cores.

Tj temperatures may refer to the temperature at the junction of a device's actual processing cores or other heat-generating components. They may be part of the device's thermal monitoring and management system, allowing the device itself and associated hardware to operate within safe temperature limits and optimize performance while preventing overheating. Tj temperatures may be accessed through monitoring software to provide other system components with more detailed temperature data for thermal management, diagnostic, and tuning purposes.

CPU Tj1, also known as Core Junction Temperature 1, may refer to the temperature at the junction of the CPU's actual processing cores. This temperature is more critical and accurate because it directly measures the temperature of the CPU's cores, where the actual computation takes place. Tj1 is typically higher than its associated Tcase as it represents the temperature inside the CPU die, which is where the heat is generated during operation.

Tj2, Tj3, and so on refer to additional temperature junctions or thermal sensors either elsewhere within a CPU, or in other components. These additional temperature sensors are often used for more precise monitoring and thermal management. The specific use and naming of these sensors can vary between different manufacturers and models.

The method or algorithm 400 may further comprise adjusting the valve and/or compressor, wherein increasing pressure increases the saturation temperature, whereas decreasing pressure lowers the saturation temperature. Increasing pressure may comprise constricting an opening of the valve and decreasing pressure may comprise expanding the opening of the valve.

When the system temperatures rise 411 (power limit 2 (PL2)), the method or algorithm 400 may increase pressure 412 for a higher saturation temperature (Tsat). This may involve adjusting a compressor 420 and or adjusting a valve 430 such as an electronic expansion valve (EEV). Adjusting the valve may constrict the valve opening to increase pressure 431. An increase in pressure results in an increase in temperature 435.

Increasing pressure and temperature (Raising Tsat) may indicate PL2 or higher power under cold plates. When there is a need to increase the saturation temperature (Tsat) in the evaporator, the expansion valve adjusts to restrict the flow of refrigerant. By restricting the flow, the expansion valve increases the pressure on the high-pressure side of the system (condenser), which in turn raises the temperature and pressure of the refrigerant before it enters the evaporator. This higher pressure and temperature enable the refrigerant to absorb more heat in the evaporator, achieving the desired increase in cooling capacity.

When the system temperatures drops 413 (power limit 1 (PL1)), the method or algorithm 400 may decrease pressure 414 for a higher saturation temperature (Tsat). This may involve adjusting the compressor 420 and or adjusting the valve 430. Adjusting the valve or EEV may increase the valve opening rapidly to decrease pressure 433. A decrease in pressure results in a decrease in temperature 437.

Decreasing pressure and temperature (Lowering Tsat) may indicate PL1 or lower power under cold plates. When there is a need to decrease the saturation temperature (Tsat) in the evaporator (cold plates), the expansion valve responds by allowing the refrigerant to expand rapidly. This expansion may cause a significant pressure drop. As the refrigerant expands, its pressure and temperature decrease. This decrease in pressure and temperature allows the refrigerant to absorb heat efficiently from the surroundings in the evaporator, achieving the desired cooling effect.

When the system temperature remains constant 415 or within a predefined or calculated range or threshold, the method or algorithm 400 may maintain the pressure 416. Temperatures may remain with an at most 5% (or at most 10%, or at most 20%) threshold of a set or desired temperature value to avoid repetitive adjustments of the compressor or valves. This may increase the lifespan of the individual components and thus the entire system.

In every case, the method or algorithm 400 may check the power levels 407 of the plurality of electronic components to determine the impact of the algorithm on the system. If method or algorithm 400 determines that the system remains active 403 (has not been interrupted, powered off, suspended, or terminated). The method may repeat (such as by returning to a loop point 405) and continue to monitor the temperatures 410 of the system.

The method or algorithm 400 may also include a fine-tuning feedback loop. When a feedback loop is established between a microcontroller unit (MCU) or processor and the sensors. The MCU continuously reads pressure and temperature data from the sensors and compares it to the desired setpoint. A dynamic control algorithm that automatically fine tunes based on a digital Proportional-Integral-Derivative (PID) controller is established to calculate the necessary adjustments and finetune the PID gain to the actuators based on the error between the measured and desired values.

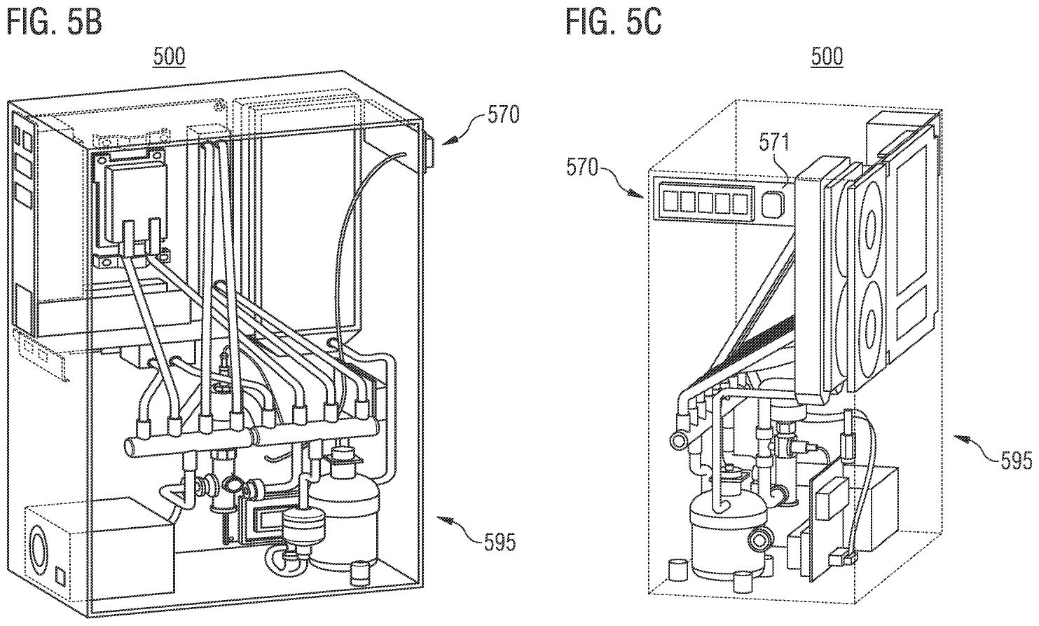

More details and optional aspects of FIG. 4 may be described in connection with examples described above (e.g. FIGS. 1A to 3) or below (e.g. FIGS. 5A to 12).

The method or algorithm 400 may be implemented on a control system. A control system may comprise interface circuitry, instructions stored on a non-transitory, machine-readable medium, and processor circuitry to execute the machine-readable instructions. The instructions may cause the processor circuitry to monitor one or more system temperatures and adjust a valve and/or a compressor of the cooling system to alter the saturation temperature of a two-phase coolant based on one or more system temperatures.

FIG. 5A shows a visualization of a two-phase cooling system for a desktop chassis. The figure shows how the system 500 may be implemented within the footprint of the desktop environment. Only the components of the autonomous tunable compressor-driven, two-phase flow cooling device are shown in FIG. 5A. The desktop chassis is omitted for clarity.

FIG. 5A shows a condenser (air-cooled heat exchanger) 510, a compressor 520, an electronic expansion valve (EEV) 530, a CPU cold plate (evaporator) 540-1, a GPU cold plate (evaporator) 540-2, a DIMM 1 cold plate (evaporator) 540-3, a DIMM 2 cold plate (evaporator) 540-4, a microcontroller 560 to control the compressor 520 and EEV 530, a condenser-to-EEV connection 511, a compressor-to-condenser connection 513, an inlet manifold 541 to parallel cold plate connections 540-1 . . . 540-4 from EEV 530, an outlet manifold 543 from cold plates 540-1 . . . 540-4 to compressor 520, a desktop motherboard 590, and a power supply 591.

FIGS. 5B and 5C show visualizations of a two-phase cooling system within a desktop chassis. These figures show how the components in FIG. 5A fit into the form factor of a typical desktop chassis with all the component fittings and brazed cold plates to components. FIGS. 5B and 5C further show an external interface 570 in the form of an LCD panel in the front of the chassis 595 displaying the current cold plate temperatures. As seen in FIG. 5C, the interface 570 may further include switches 570 for manually adjusting set point (Tset) temperatures. The interface 570 may be connected to the processor or microcontroller, which may adjust the valve and/or the compressor based on input from the external interface.

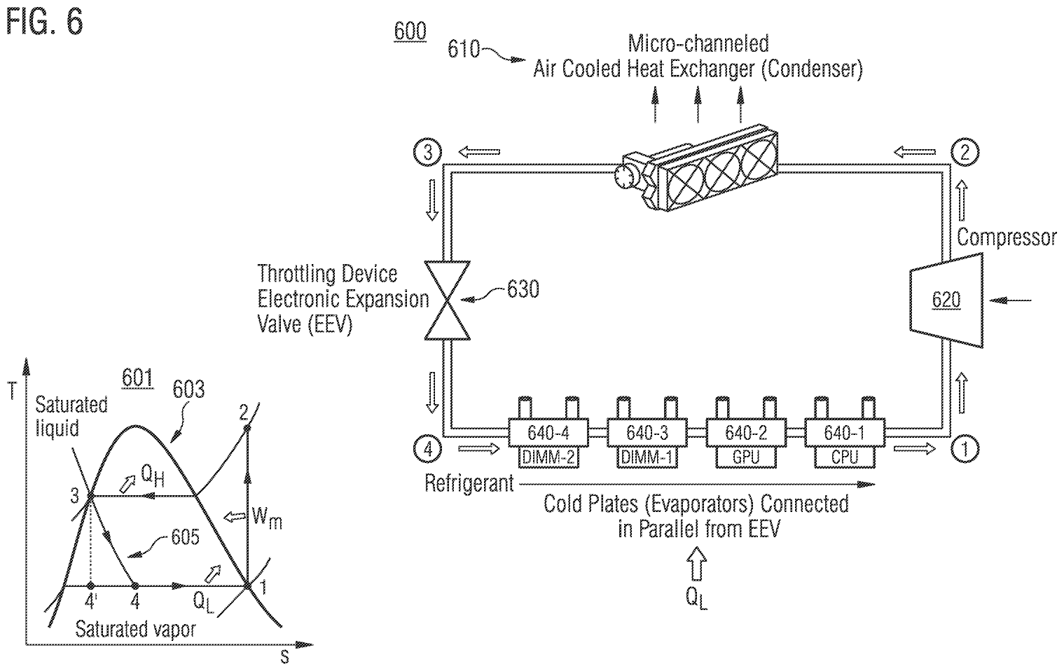

A compressor 520 is responsible for compressing the working fluid or refrigerant gas, increasing its pressure, and subsequently raising its saturation temperature. The compressor 510 accepts from cold plates, a low-temperature, low-pressure refrigerant vapor, and compresses it into a high-temperature, high-pressure vapor. The microchannel cold plates cool the heat-dissipating devices (CPU, GPU, and DIMMs) with individual cold plates as shown in the FIG. 6 block diagram. When the refrigerant simultaneously (in parallel) passes through multiple cold plates picking up the heat, the mixture entering the compressor 520 becomes super-heated. This high temperature/pressure vapor then enters the condenser (heat exchanger) 510.

The compressed vapor flows through the micro-channeled condenser 510 and transforms into a sub-cooled liquid. A condenser 510 is essentially a heat exchanger with fans blowing on it (forced convection) to dump the heat into the ambient air from the heat exchanger. As the heat is dumped into ambient surroundings, the energy stored in the high-pressure refrigerant/gas is released and the refrigerant coolant gives up its latent heat as it reverts to a hot liquid. The working fluid/refrigerant then exits the condenser 510 and enters the expansion valve 530.

In the electronic expansion valve (EEV) 530 the working fluid/refrigerant undergoes a relative pressure drop causing hot fluid to vaporize, lowering the temperature of the refrigerant system. Now, the low-temperature refrigerant exits the expansion valve and flows into the evaporators 540-1 . . . 540-4. In this system 500, the throttling device (EEV) 530 is automatically tuned by the microcontroller 560 for the required pressure needed to maintain the Tsat. This valve 530 is designed to maintain the desired pressure within the system. It can be set to a specific pressure threshold level, which corresponds to the optimal target saturation temperature for the refrigerant coolant. For instance, for Power Levels 2 (PL2 or higher power scenarios such as overclocking applications, as the power shoots up, temperature sensors pick up the Tj-rise and the temperature increases in strategic cases, the micro-controller automatically increases the pressure to increase the Tsat for maximum cooling efficiency.

In the cold plates (evaporators) 540-1 . . . 540-4 the two-phase working fluid/refrigerant changes its phase into vapor inside the cold plates as it picks up heat. This cycle is repeated in a closed loop within the desktop environment as shown in the block diagram of FIG. 6. Cold plates are components through which the working fluid refrigerant mixture flows where the heat is transferred from the high-power component to the refrigerant. In this design, the cold plate fins are microchannels that are oriented parallel to each other and the refrigerant passes through it for high heat dissipative capability.

The plurality of evaporator structures may be fluidly connected in series. The cold plates on the CPU, GPU, and DIMMs may all be connected in series when there are only a few dissipating components inside desktop systems where a total dissipating power is up to 1 kW. Connecting the evaporators 540-1 . . . 540-4 in series may be efficient when the heat dissipated from each of the electronic devices is not enough to change the two-phase working fluid/refrigerant entirely from a liquid to a gas. In this manner, the two-phase refrigerant can pass from evaporator to evaporator becoming more gaseous as it picks up heat. This allows less tubing to be used in the system as each evaporator is connected in series instead of to a common inlet and outlet manifold 541, 543.

The plurality of evaporator structures may be fluidly connected in parallel. In systems with high heat dissipation, the cold plates on the CPU, GPU, and DIMMs may all be connected in parallel. Connecting the evaporators 540-1 . . . 540-4 in parallel allows the full cooling effect of the two-phase coolant to be used on each component equally. Thus a parallel cooling structure avoids issues with a last placed component in a series only receiving a working fluid that is mostly or completely a gas.

Mixed systems are also possible. For example, high-powered components, such as a CPU or GPU, may be connected in parallel to receive a dedicated portion of two-phase coolant while lower-powered components, such as DIMMs may be connected in series to save piping or chassis space while more efficiently using the two-phase coolant.

The cooling system 500 may further comprise one or more temperature sensors providing one or more system temperatures, wherein the one or more temperature sensors are located at least one of a vapor line, a liquid line, a reservoir, the inlets of the plurality of cold plates, or the outlets of the plurality of cold plates.

Pressure and temperature sensors such as thermocouples or thermostats are placed at several critical points in the system to monitor and regulate pressure to control the temperature. These sensors will provide real-time data on the system's pressure and temperature. Thermocouples can be placed in the liquid line, vapor line, manifold, inlet, and outlet fittings of all the cold plates and the primary reservoir chamber. These are points where it may be advantageous to maintain a specific temperature.

The processor or MCU 560 of the cooling system 500 may further monitor a plurality of system pressures and adjust the valve and/or the compressor to alter the saturation temperature based on the plurality of system pressures.

The use of a digital microcontroller is prevalent in modern industrial systems design these days. An MCU may be centrally connected to all the different components to monitor pressure, temperature, and other vital parameters as well as able to fine-tune the compressor and the expansion valve automatically without user intervention. The system may also provide the ability for a user to change the parameters if desired ad hoc.

The cooling system 500 may comprise a motherboard 590. The motherboard 590 may provide one or more system temperatures to the processor or MCU 560. An MCU may read the temperature from all the temperature sensors and adjust the pressure control valve accordingly. When the temperature deviates from the desired setpoint, the microcontroller sends a signal to the pressure control valve to adjust the pressure in the system accordingly.

The processor 560 of the cooling system 500 may adjust the valve and/or the compressor to keep the hottest electronic device temperature within a threshold range. The MCU may continuously monitor the temperature and adjust the pressure control valve to maintain the desired temperature. This can be for the whole system or the hottest component, such as the CPU. If the temperature rises above the setpoint, the controller will open the valve to reduce pressure, which, in turn, lowers the saturation temperature. Conversely, if the temperature falls below the setpoint, the controller will close the valve to increase pressure and raise the saturation temperature. Thus, by dynamically adjusting/regulating the pressure, a desired optimal saturation temperature is achieved and effectively regulated.

The high-pressure, sub-cooled liquid from the condenser then flows through the expansion valve and transforms to a low-pressure, two-phase flow ready to enter the cold plates and this cycle repeats. An expansion valve may be compliant with a variety of refrigerants. These valves should precisely regulate the flow of refrigerant into the cold plates, allowing for fine control over the cooling or refrigeration process. An expansion valve is used to respond to the variable capacity of the refrigerant and optimize performance and efficiency.

The expansion valve accomplishes these adjustments by regulating the size of the valve opening. Modern expansion valves are often electronically controlled and can modulate their opening based on feedback from temperature and pressure sensors in the system. This allows for precise control of the refrigerant flow rate, which, in turn, controls the pressure and temperature at the evaporator inlet. An expansion valve plays a crucial role in adjusting the pressure and temperature of the refrigerant as it enters the evaporator, making it an essential component for controlling the cooling capacity and achieving the desired saturation temperature in a vapor compression refrigeration system.

The cooling system 500 may further comprise pressure sensors providing the plurality of system pressures. The pressure sensors may be located at least before an inlet of the valve and after an outlet of the valve. The primary purpose of the expansion valve's role is to regulate the flow of refrigerant from the high-pressure, high-temperature side (incoming from the condenser) to the low-pressure, low-temperature side (flowing into the cold plates). The expansion valve adjusts the pressure and temperature of the refrigerant to ensure efficient cooling. Having pressure sensors before and after the valve allows for better regulation of the flow of the two-phase coolant.

Pressure sensors may be further located at the inlets of the plurality of cold plates and the outlets of the plurality of evaporator structures. The expansion valve accomplishes these adjustments by regulating the size of the valve opening. Modern expansion valves are often electronically controlled and can modulate their opening based on feedback from temperature and pressure sensors in the system. Knowing the pressure reading at the evaporator inlets (for example, at each evaporator inlet in a series) allows the system to know the pressure level of a two-phase coolant as it passes across the evaporator plates. This allows for precise control of the refrigerant flow rate, which, in turn, controls the pressure and temperature at the evaporator inlet. In summary, the expansion valve plays a crucial role in adjusting the pressure and temperature of the refrigerant as it enters the evaporator, making it an essential component for controlling the cooling capacity and achieving the desired saturation temperature in a vapor compression refrigeration system.

More details and optional aspects of FIGS. 5A to 5C may be described in connection with examples described above (e.g. FIGS. 1A to 4) or below (e.g. FIGS. 6 to 12).

FIG. 6 shows a diagram of a two-phase cooling system with a graph of the thermodynamic state point of the vapor compression cycle. Specifically, FIG. 6 is a diagram illustration of the refrigeration system in a closed loop and the thermodynamic state point of the vapor compression cycle. The diagram 600 shows a cold plate for CPU 640-1, a cold plate for GPU card 640-2, and cold plates for DIMMs 640-3, 640-4, and are all connected using a single compressor, condenser, and an electronic expansion valve thermal solution. All the cold plates are connected in parallel to the inlet and outlet manifolds that are brazed to ensure a leak-free environment inside the desktop chassis. The circled numbers 1, 2, 3, and 4 on the diagram 600 correspond to different states of the coolant or refrigerant in the closed loop. The numbers correspond to the numbers in graph 601. The graph 601 shows the temperature (T) of the coolant on the y-axis and the saturation(s) of the coolant on the x-axis. The curve 603 shows at which points the coolant transitions between liquid and gas. At stage 1, where the coolant has exited the evaporators 640-1 . . . 640-4, the coolant is a saturated vapor. Its temperature remains relatively low because it has used the heat from the evaporators to transition from a liquid to a gas. At stage 2, the coolant is compressed by the compressor 620 into a liquid where its temperature increases to its highest point. At stage 3, where the coolant has exited the heat exchanger 610, the coolant is a saturated liquid. Its temperature has dropped from its peak at stage 2 but it has not cooled to its greatest extent. At stage 4, the coolant is expanded by the expansion valve, cooling the refrigerant even further. Here it can begin absorbing heat again from the evaporators 640-1 . . . 604-4 and remain at a relatively low temperature as it transitions from a liquid to a gas and repeats the cycle.

Since the two-phase flow utilizes the latent heat of vaporization to absorb heat from the processors, the exit temperature of the fluid cold plate remains consistent with the inlet temperature. This allows for the possibility of arranging multiple processors or cold plates in series while maintaining uniform heat dissipation, provided the fluid flow rate for the entire loop is appropriately sized, and the inlet fluid experiences minimal sub-cooling. Consequently, case or silicon junction temperatures can be kept nearly constant across all processors.

The microcontroller controls the pressure of the compressor to regulate an optimal output of Saturation Temperature (Tsat) based on the readings from different thermocouples/temperatures and controls the pressure valves to open/close in a dynamic closed loop environment without any user intervention. Temperature feedback from thermocouples may be placed in strategic locations. The pressure of the compressor 620 is regulated to control the Saturation Temperature of refrigerant coolants. Tsat is where the refrigerant changes its phase from liquid to vapor. Enabling Tsat_optimal is crucial for removing high heat transfer loads in the shortest transient time possible.

The microcontroller will monitor the temperature at several different locations, vapor line, liquid line, and QDs (incoming and outgoing ports) of all the cold plates at the manifold. It may either open or close the pressure valve to control adequate optimal pressure to precisely control the saturation temperature for excessive cooling based on the power levels dissipated.

When there is a need to decrease the saturation temperature (Tsat) in the evaporator (cold plates), the expansion valve responds by allowing the refrigerant to expand rapidly. This expansion may cause a significant pressure drop. This may happen under PL1 or lower power under cold plates. As the refrigerant expands, its pressure and temperature decrease. This decrease in pressure and temperature allows the refrigerant to absorb heat efficiently from the surroundings in the evaporator, achieving the desired cooling effect.

Conversely, when there is a need to increase the saturation temperature (Tsat) in the evaporator, the expansion valve adjusts to restrict the flow of refrigerant. This may happen under PL2 or higher power under cold plates. By restricting the flow, the expansion valve increases the pressure on the high-pressure side of the system (condenser), which in turn raises the temperature and pressure of the refrigerant before it enters the evaporator. This higher pressure and temperature enable the refrigerant to absorb more heat in the evaporator, achieving the desired increase in cooling capacity.

The whole system is a closed loop with a minimalistic real estate footprint and removes large heat loads from the desktop CPU, GPU, and DPUs. A single thermal solution with multiple cold plates are brazed in parallel to the inlet and outlet manifolds to cool multiple processors such as CPU, GPU, DPU, and DIMMs. There may be no leaks inside since the plumbing lines and fittings are all brazed into a closed loop.

The microcontroller reads the junction temperature and the case temperatures of all the devices from the main motherboard and tunes the thermal solution's efficacy accordingly. If the temperature is high, the microcontroller tunes and tailors the thermal capability of the compressor and expansion valve to increase the pressure and saturation temperature (Tsat). Consequently, when the temperature drops, the expansion valve opens up to drop the pressure and the saturation temperature.

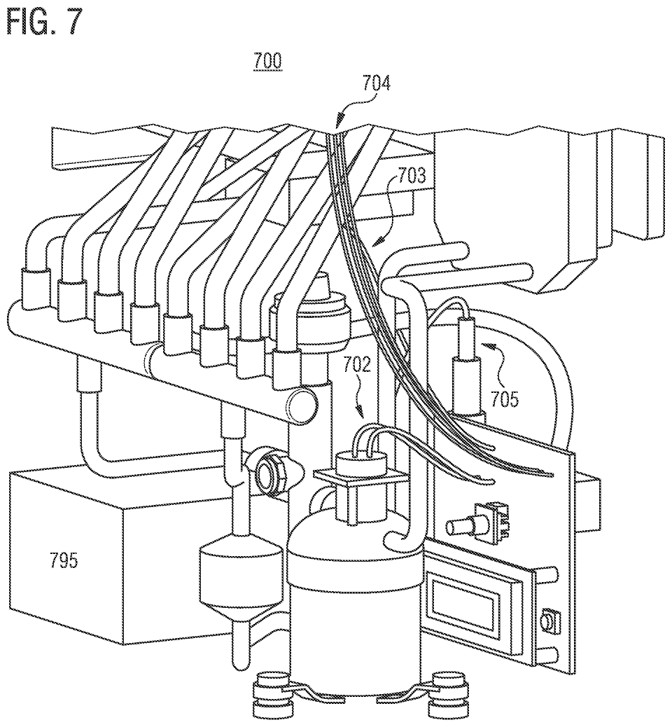

More details and optional aspects of FIG. 6 may be described in connection with examples described above (e.g. FIGS. 1A to 5C) or below (e.g. FIGS. 7 to 12).

FIG. 7 shows a visualization of a two-phase cooling system 700 with connections to a processor. Specifically, the figure shows connections 702, 703 between the processor or microcontroller 760 the compressor 720, and valve 730. These connections 702, 703 may also power the devices. This is possible with a connection 705 to the power supply 795 The microcontroller unit 760 may also be connected 709 to the motherboard (not shown) to get the temperature data (Tcase and Tj) and the control algorithm appropriately tunes the compressor and EEV for optimal saturation temperature resulting in optimal cooling.

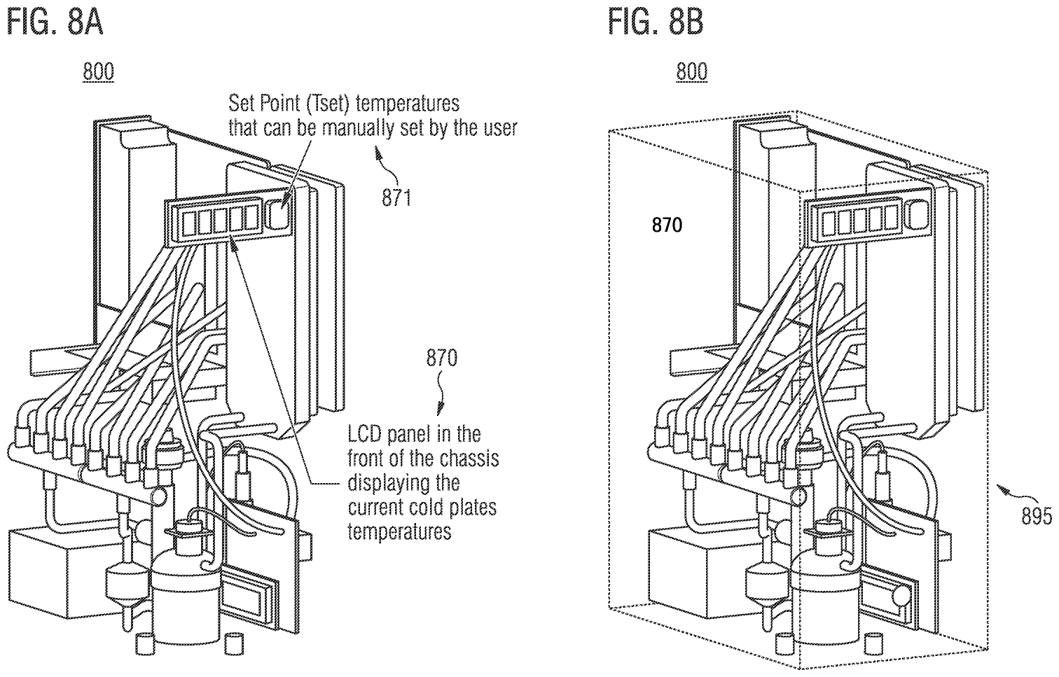

More details and optional aspects of FIG. 7 may be described in connection with examples described above (e.g. FIGS. 1A to 6) or below (e.g. FIGS. 8A to 12).

FIGS. 8A and 8B show visualizations of a two-phase cooling system 800 with a connection to an interface. The cooling system may comprise an external interface connected to the processor. The processor may adjust the valve and/or the compressor further based on input from the external interface.

FIG. 8A shows the system 800 without a chassis. FIG. 8B shows the system 800 with a chassis 895 transparently. Both figures show an external interface 870 in the form of an LCD panel in the front of the chassis 895 displaying the current cold plate temperatures. The interface 870 may further include switches 871 for manually adjusting set point (Tset) temperatures. This feature allows for a user to manually control the set point of the individual cold plates cooling the power dissipative components and this is controlled at will by the end user. When the processor or MCU reads the different junction temperatures (Tj) from different components, it automatically adjusts the set point temperature by controlling the compressor, electronic expansion valve, etc.

The user can adjust the temperature set points for the cold plates via the LCD panel switches provided at the front chassis of the desktop. The user's desired cold plate set point temperature can be increased or decreased using the switches presented outside the desktop chassis for manual control. Then depending on the current cold plate and compressor temperatures, the algorithm will determine the temperature difference required to reach the desired set point. At this point, the control algorithm will tune the compressor to target the desired set point temperature and will adjust the saturation temperature (either decreases or increases). The control algorithm will adjust the saturation temperature (increase Tsat for potential overclocking) or decrease the Tsat when temperature sensors show low temperature). The Temperature set point (Tset) control feature may manually override and ad hoc control provided to manually set the cold plate temperatures temper. However, the microcontroller may revert control back to the algorithm if certain conditions are met. These could be due to pressure increases or decreases, energy usage, time, such as the time a compressor is running at high RPMs, and other factors relating to the efficiency and health of the computing system.

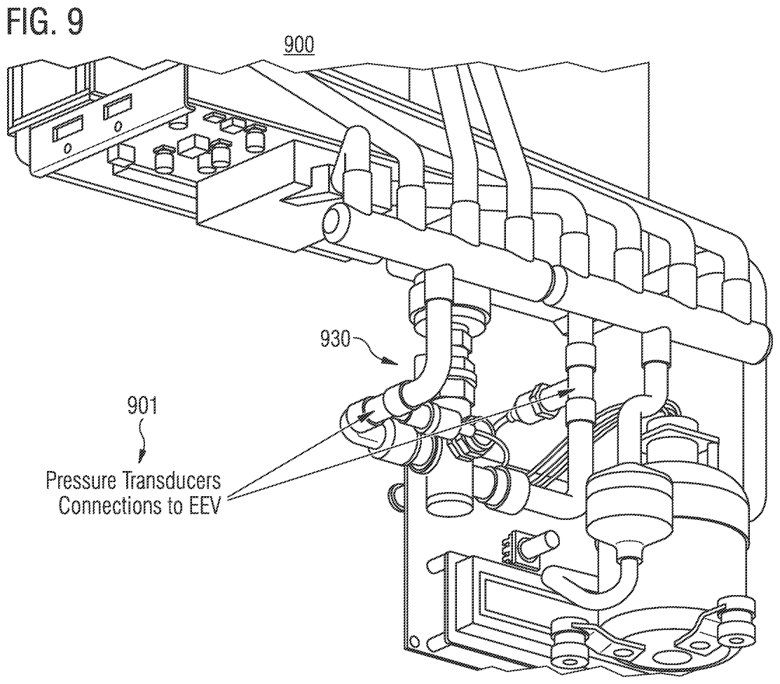

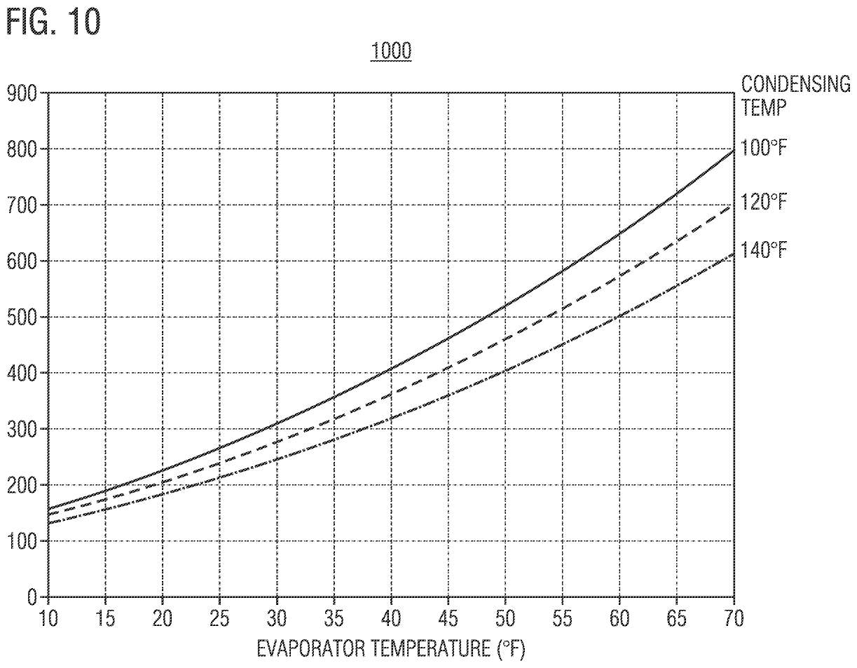

More details and optional aspects of FIGS. 8A and 8B may be described in connection with examples described above (e.g. FIGS. 1A to 7) or below (e.g. FIGS. 9 and 10).

FIG. 9 shows a visualization of a two-phase cooling system 900 with pressure transducer connections. Specifically, it shows two pressure transducer connections 993 to the expansion valve.

Two pressure sensors or transducers 901 may be connected to the expansion valve 930 as shown in FIG. 9. The control algorithm may use this data to adjust the expansion valve when there is a mismatch in the pressure to be dropped to reach the saturation temperature. For instance, the calculation, shown below, calculates the entire phase change process from the evaporator to the expansion valve. As mismatch is determined based on known compressor information.

Table 1 shows an example compressor operating power (W) based on condenser temperature and required evaporator (cold plate) temperature.

TABLE 1

| Condenser | Compres- | | | | | | | |
|---|---|---|---|---|---|---|---|---|
| Tempera- | sor Speed | Evaporator Temperature (° F.) | | | | | | |
| ture (° F.) | (RPM) | 10 | 20 | 30 | 40 | 50 | 60 | 70 |
| 100 | 3000 | 77 | 64 | 60 | 57 | 55 | 54 | 53 |
| | 4000 | 89 | 82 | 78 | 76 | 75 | 74 | 73 |
| | 4500 | 93 | 89 | 87 | 86 | 85 | 85 | 84 |
| | 5000 | 99 | 99 | 98 | 98 | 98 | 98 | 98 |
| | 6000 | 109 | 117 | 121 | 124 | 126 | 128 | 129 |
| 120 | 3000 | 69 | 73 | 76 | 78 | 79 | 80 | 80 |
| | 4000 | 89 | 95 | 98 | 101 | 103 | 105 | 106 |
| | 4500 | 97 | 105 | 109 | 113 | 115 | 117 | 118 |
| | 5000 | 105 | 114 | 120 | 124 | 127 | 130 | 131 |
| | 6000 | 121 | 133 | 141 | 148 | 153 | 156 | 159 |
| 140 | 3000 | 72 | 85 | 92 | 99 | 104 | 108 | 111 |
| | 4000 | 95 | 110 | 119 | 127 | 132 | 137 | 140 |
| | 4500 | 106 | 122 | 132 | 140 | 146 | 150 | 154 |
| | 5000 | 118 | 135 | 145 | 154 | 160 | 165 | 169 |
| | 6000 | 139 | 157 | 170 | 181 | 188 | 195 | 200 |

Specifically, the calculation determines the mass flow rate required from the compressor and expansion valve to cool 500 W on a cold plate and cool it to 75° F. (23.889° C.). The microcontroller will throttle the compressor speed and vary the compressor operating power (Q) based on the condenser temperature feedback and compare it to the embedded data in the microcontroller provided in Table 1, above.

Desired cold plate temperature (T)=75° F. and Corresponding pressure=69.9 psi

Calculate the mass flow rate (m) required to maintain the cold plate temperature at 75° F. (23.889° C.).

$$\dot{m} = \frac{Q}{{h}_{i n} - {h}_{out}}$$

Where Q is the cooling power required to dissipate the silicon heat load (given for each power level).

To find out hₒᵤₜ, we need to calculate h_{isentropic} interpolating between the enthalpy values provided in the data. And from the thermodynamic data of the refrigerant:

Liquid Enthalpy→hᵢₙ_{_{liquid}} at 69.9 psi (75° F.) is 35.94 BTU/lb.

Vapor Enthalpy→hᵢₙ_{ᵥₐₚₒᵣ} at 69.9 psi (75° F.) is 108.1 BTU/lb.

Liquid Entropy→sᵢₙ_{_{liquid}} at 69.9 psi (75° F.) is 0.0752 Btu/R-lb.

Vapor Entropy→sᵢₙ_{ᵥₐₚₒᵣ} at 69.9 psi (75° F.) is 0.2101 Btu/R-lb.

Re-arranging the equation [1] to substitute values from the thermodynamic data of the refrigerant:

$$\dot{m} = \frac{129 W}{{h}_{i n , vapor} - {h}_{isentropic}}$$

Now, calculate the isentropic (h_{isentropic}) at 69.9 psi and 23.889° C. (75° F.) using the entropy values:

sₒᵤₜ at 69.9 psi and 23.889° C. (75° F.): 0.2101 Btu/R-lb (Same as sᵢₙ_{ᵥₐₚₒᵣ})

Thus, Isentropic Entropy (sₒᵤₜ) at 69.9 psi and 75° F.→0.2101 Btu/R-lb.

We need to find out the corresponding enthalpy at 69.9 psi.

let's identify the two data points (70° F. and 80° F.) closest to the isentropic entropy (0.2101 Btu/R-lb) in the entropy data array:
For s₁=0.2098 Btu/R-lb, h1=108.8 BTU/lb
For s₂=0.2102 Btu/R-lb, h2=107.3 BTU/lb

Now, we can interpolate to find h_{isentropic} at sₒᵤₜ=0.2101 Btu/R-lb

$${h}_{isentropic} = {h}_{1} + \frac{{s}_{o u t} - {s}_{i n}}{{s}_{2} - {s}_{1}} \cdot ( {h}_{2} - {h}_{1} )$$

Substituting,

$${h}_{i sentropic} = 108.8 + \frac{0.2101 - 0.2098}{0.2102 - 0.2098} \cdot ( 107.3 - 108.8 )$$

$${h}_{isentropic} = 107.6 \; 75 \frac{BTU}{lb}$$

$$\dot{m} = \frac{129 W}{108.1 - 107.675}$$

$$\dot{m} = 303.53 lb / h$$

In the third stage saturated liquid phase, pressure data P2=P3=1600 K·pa corresponding to the Tsat of 57.92° C. and in the next stage, the pressure (p4) has to drop to 600 K·pa to reach the target set point temperature (Tsat) of 21.58° C. If the expansion valve does not drop the pressure precisely to 600 K. Pa, the target set point temperature may not be reached. Pressure transducers will pick up this data before and after the EEV and pass it on to the microcontroller unit. The control algorithm in the microcontroller unit will adjust the valve in the EEV to accurately drop the pressure required to reach the precise Tsat. This is done iteratively in the code and microcontroller until the precise pressure is reached. Thus, the control algorithm of the microcontroller effectively uses the pressure data to reach a tailored target temperature set by the user.

The control algorithm calculates the required mass flow rate needed to cool the cold plate for the target set point temperature. Once the code executes this set of instructions and identifies the optimal mdot needed, then the code fetches the compressor data from the compressor array data that is hardcoded and embedded in the code. Table 2, below, is an example spec sheet that the compressor manufacturer publishes for most refrigerants.

TABLE 2

| Condenser | Compres- | | | | | | | |
|---|---|---|---|---|---|---|---|---|
| Tempera- | sor Speed | Evaporator Temperature (° F.) | | | | | | |
| ture (° F.) | (RPM) | 10 | 20 | 30 | 40 | 50 | 60 | 70 |
| 100 | 3000 | 72 | 114 | 156 | 213 | 270 | 346 | 422 |
| | 4000 | 101 | 155 | 209 | 283 | 356 | 454 | 552 |
| | 4500 | 115 | 175 | 235 | 317 | 400 | 508 | 617 |
| | 5000 | 129 | 194 | 260 | 349 | 439 | 558 | 677 |
| | 6000 | 156 | 232 | 309 | 414 | 518 | 657 | 796 |
| 120 | 3000 | 69 | 104 | 140 | 188 | 237 | 301 | 366 |
| | 4000 | 98 | 145 | 191 | 255 | 318 | 402 | 486 |
| | 4500 | 113 | 165 | 217 | 288 | 358 | 452 | 546 |
| | 5000 | 126 | 181 | 237 | 312 | 388 | 491 | 594 |
| | 6000 | 152 | 215 | 277 | 362 | 448 | 568 | 588 |
| 140 | 3000 | 58 | 90 | 122 | 165 | 209 | 267 | 324 |
| | 4000 | 78 | 120 | 162 | 220 | 278 | 355 | 431 |
| | 4500 | 87 | 135 | 182 | 247 | 312 | 399 | 485 |
| | 5000 | 102 | 153 | 204 | 273 | 343 | 435 | 527 |
| | 6000 | 131 | 188 | 246 | 325 | 404 | 508 | 612 |

The sample calculation shown above is to calculate the required mass flow rate by the microcontroller so that it can instruct the compressor to deliver the right amount of RPM required and not operate in full blast. Table 2 is experimental data for an example model that has a maximum cooling capacity of 796 W when certain criteria are met. For a condenser temperature of say 100° F. and required cold plate (evaporator) temperature of say 70 F, the power that can be dissipated varies by the operating speed of the compressor and is given in several RPMs. For instance, 796 W of power can be cooled maintaining the cold plate temperature at 70° F. when two criteria are met: (a) when the compressor is operating at 6000 RPM and (b) when the condenser is maintained at 100° F. This data provides a window of opportunity to operate the compressor at several different speeds.

More details and optional aspects of FIG. 9 may be described in connection with examples described above (e.g. FIGS. 1A to 8B) or below (e.g. FIGS. 10 to 12).

FIG. 10 shows a graph 1000 of experimental data for a compressor of a two-phase cooling system. The plots in FIG. 10 show the cooling capacity as a function of the condenser's temperature for each operating speed of the compressor. The FIG. 9 plot is shown for 6000 RPM. Table 2 has data for all the different speeds at which the compressor can operate and is embedded in the microcontroller. As the ability to cool the condenser is compromised, so is the ability to remove heat effectively as can be seen in the graph. Thus, the compressor's efficient cooling is also a function of the condenser's ability to dump the energy from the circulating refrigerant into the ambient environment.

The condenser's fans are all PWM capable and controlled by the microcontroller. Not only the compressor's speed is controlled by the control algorithm, but the condenser's fan speed is also controlled by the microcontroller's algorithm to reach a specific condenser temperature. For an increase in the condenser's temperature, fan speed is compromised and to decrease the condenser's temperature, fan speed is increased, and the control algorithm interpolates the compressor's data from the code to make these decisions to ultimately cool the cold plate to desired set point and power.

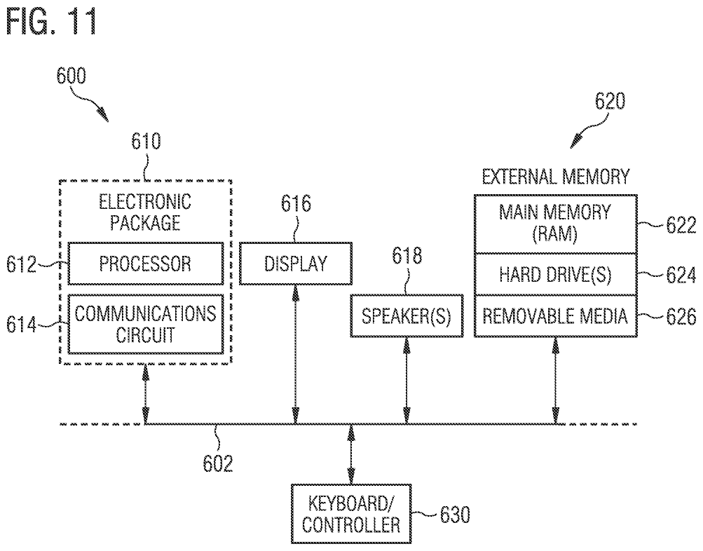

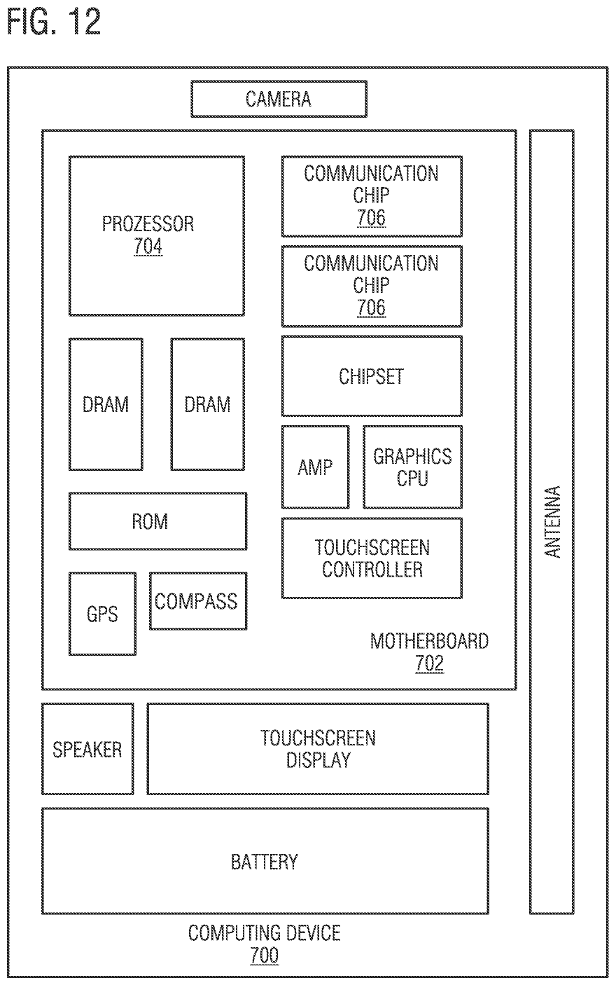

More details and optional aspects of FIG. 10 may be described in connection with examples described above (e.g. FIGS. 1A to 9) or below (e.g., FIGS. 11 to 12).

A further sample calculation is shown below to calculate the phase change mixture from the refrigerant. The microcontroller drives the compressor dynamically and the compressor drives the refrigerant (R-134a shown in these calculations) through a condenser (air-cooled heat exchanger), an expansion valve, and cold plates (evaporators). This further calculation is shown to maintain the cold plate at 21.58° C. (70° F.).

All the calculations may be automatically done by the code embedded in the microcontroller to control, appropriate pressure levels at each stage to get the desired temperature for phase change and to maintain the cold plate at the desired target temperature.

The hot refrigerant gas leaving the compressor condenses in the condenser via heat transfer to the ambient environment (forced convection via air cooling).

The pressure drops as the refrigerant passes through the expansion valve. The drop in pressure lowers the saturation temperature of the refrigerant.

This lower saturation temperature of the refrigerant enables it to boil in the evaporator as it absorbs heat from the cold plates (evaporators).

The refrigerant then returns to the compressor to repeat the cycle. The controller turns the compressor on and off to maintain the refrigerator compartment temperature within a band around the desired temperature.

Stage 1: Saturated Vapor (high temperature, high-pressure vapor) Compressor

To maintain 70° F. (21.58° C.) at the cold plate, that is T1=Tevap=21.58° C., the appropriate pressure, enthalpy, and entropy are obtained from thermodynamic tables of the refrigerant R-134a corresponding to this desired target temperature for saturated vapor.

$$p 1 ( p1\_Sat ) = 600 K \cdot pa$$

$$h 1 = ( h1\_sat ) = 259.19 kJ / kg \cdot K$$

$$s 1 = ( s1\_sat ) = 0.9 \; 097 kJ / kg \cdot K$$

Stage 2: Superheated Vapor (hot liquid, energy released to ambient by Condenser)

Here, s1=s2

$$s 1 = ( s1\_sat ) s 2 = ( s2\_sat ) = 0.9 \; 097 kJ / kg \cdot K$$

$$p 2 = 1600 K \cdot Pa$$

$$h 2 = ( h2\_sat ) = 278.2 kJ / kg \cdot K$$

$$T 2 = 57.92 ° C .$$

This is automatically calculated by the code in the microcontroller. The appropriate pressure, enthalpy, and entropy are obtained from thermodynamic tables of the refrigerant R-134a corresponding to this entropy for superheated vapor.

Stage 3: Saturated Liquid (lower pressure, lower temperature of the refrigerant at exits the Electronic Expansion Valve)

$$p 2 = p 3 = 1600 K \cdot Pa$$

$$T 2 = 57.92 ° C .$$

$$h 2 = ( h2\_sat ) = 134.02 kJ / kg \cdot K$$

$$s 3 = ( s3\_sat ) = 0.4 \; 714 kJ / kg \cdot K$$

Stage 4: Isentropic

$$p 4 = p 1 = 600 K \cdot Pa$$

$$h 3 = h 4 = 134.02 kJ / kg \cdot K$$

$$s 3 = ( s3\_sat ) = 0.4 \; 714 kJ / kg \cdot K$$

$$T 4 = T 1 = ( Tsat ) = 21.58 ° C .$$

$$h4\_ssat = h1\_sat for vapor = 259.19 kJ / kg \cdot K$$

$$h4\_sat for liquid = 79.48 kJ / kg \cdot K$$

For the mixture

$$X = ( h 4 - h4\_sat \_liq ) / ( h4sat\_vap - h4sat\_liquid )$$

$$X = ( 134.62 - 79.48 ) / ( 25 \; 9 \text{.19} - 79. 48 )$$

$$X = 54.54 / 179.71$$

$$X = 0.3035$$

$$s1\_vap = S4\_vap = 0.9 \; 097 kj / kg \cdot K$$

$$s4\_sat \_liq = 0.2 \; 999 kj / kg \cdot K$$

$$X = s 4 - sat\_liq / ( sat\_vap - sat\_liq )$$

This is to find out the s4 which is the mixture of liquid+vapor
s4=0.485 Kj/kg·K which corresponds to (Tsat) of 21.58° C.

An autonomous tunable compressor-driven two-phase cooling device that cools multiple processors (such as CPU, GPU, DPU, and DIMMs) simultaneously in an attractive form factor for cooling desktop components up to 1 kW and beyond. Desktop computer power is increasingly shooting up with power hungry gaming enthusiasts and overclocking experts demanding more power turn towards liquid cooling. The cooling system, including the compressor, heat exchanger, and valve may be designed for an increased power dissipative capability beyond 1 kW. For any thermal power design, the compressor must be adequately sized for the potential power consumption, including safety buffers such as for overclocking. Thus, the compressor may be adequately sized for higher powers. The cooling system may be made to operate for cooling 1 kW to 100 kW or more if the compressors are sized for the packages being cooled. A compressor capability to cool a plurality of cold plates all totaling 1 kW may be adequate for a small desktop form factor. However, a higher capable compressor in the desktop form factor may handle 5 kW, 10 kW, or more.

Desktop computer power is already demanding close to 1 kW, and thus the cooling system may provide an exceptional benefit for those systems beyond conventional cooling. The microcontroller receives the temperature (Tcase and Tj) data from the motherboard sensors and autonomously tunes the compressor and EEV based on the control algorithm to get optimal cooling from the compressors either by increasing or decreasing the saturation temperature. This does not stress the compressor to work at full blast all the time. The Microcontroller algorithm compares the compressor data and the refrigerant thermodynamic data embedded in the microcontroller to perform all calculations dynamically (such as operating power required by the compressor, fan speed, and compressor speed) as shown in the appendices for an efficient and energy-saving implementation.

The control algorithm calculates the saturation temperature either autonomously or based on the user temperature target set point as described above. The control algorithm further calculates the Tsat based on the Tease and Tj readings from the temperature sensors on the motherboard fetched by the microcontroller from onboard temperature sensors. Or the control algorithm calculates the Tsat based on the user's desired temperature set points for the cold plates. The control algorithm dynamically varies the compressor operating power, RPM to reach a desired set point temperature for maximum energy efficiency.

The cooling system may further be configured to adjust the operation of at least one of the valves or the compressor according to an eco-friendly threshold. The system may adjust the operation of the valves or the compressor based on factors to improve the efficiency of the total system. For example, the microcontroller may continuously monitor and optimize the temperature setpoint of the cooling system based on external factors, such as ambient temperature and humidity. By adjusting the setpoint dynamically, the system can maintain the desired temperature while minimizing the runtime of the compressor. This approach helps conserve energy and ensures that the compressor operates in an environmentally friendly manner by avoiding excessive cooling when not required. In another example, the microcontroller may allow an elevated but safe temperature in the system if power consumption from the compressor is deemed excessive. For example, if the compressor runs at a high RPM past a time threshold or exceeds a power draw threshold in amount or duration. The microcontroller may also comprise a clock and be able to determine if the compressor should run at a lower RPM during peak power periods (e.g. during daylight hours) compared to lower power periods where energy is less expensive (e.g. during the night).

The microcontroller may continuously monitor the system for refrigerant leakage by setting and monitoring leakage thresholds. This may be determined if data from temperature and pressure sensors detect a deviation from normal operating conditions. Such as a detectable pressure drop over time or an increase in temperature over time for similar operating conditions. If the refrigerant leakage surpasses a predefined threshold, the microcontroller can trigger alarms or initiate shutdown procedures to prevent further environmental impact. This proactive approach to refrigerant management helps maintain the system's eco-friendliness by reducing greenhouse gas emissions as well as flammability and toxicity issues that may be associated with refrigerant leaks.

The concepts here describe a novel concept where a compressor with different compliant refrigerant data along with the compressor varying specs such as operating power, speed, etc., are made available to an on-board microcontroller that has an embedded sophisticated control algorithm that controls the entire system for maximum efficiency. The autonomous tunable device is completely in a closed loop with fully brazed components. This provides a leak-free and emissions-free performance. Overall the design of the cooling system creates a safe, environment-friendly self-contained thermal solution in an adequately packaged form factor. The aspects and features described in relation to a particular one of the previous examples may also be combined with one or more of the further examples to replace an identical or similar feature of that further example or to additionally introduce the features into the further example.

FIG. 11 is a block diagram of an electronic apparatus incorporating at least one electronic assembly and/or method described herein.

Electronic apparatus 600 is merely one example of an electronic apparatus in which forms of the electronic assemblies and/or methods described herein may be used. Examples of an electronic apparatus 600 include but are not limited to, personal computers, tablet computers, mobile telephones, game devices, MP3 or other digital music players, etc. In this example, electronic apparatus 600 comprises a data processing system that includes a system bus 602 to couple the various components of the electronic apparatus 600. System bus 602 provides communications links among the various components of the electronic apparatus 600 and may be implemented as a single bus, as a combination of busses, or in any other suitable manner.

An electronic assembly 610 as described herein may be coupled to system bus 602. The electronic assembly 610 may include any circuit or combination of circuits. In one embodiment, the electronic assembly 610 includes a processor 612 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that may be included in electronic assembly 610 are a custom circuit, an application-specific integrated circuit (ASIC), or the like, such as, for example, one or more circuits (such as a communications circuit 614) for use in wireless devices like mobile telephones, tablet computers, laptop computers, two-way radios, and similar electronic systems. The IC can perform any other type of function.

The electronic apparatus 600 may also include an external memory 620, which in turn may include one or more memory elements suitable to the particular application, such as a main memory 622 in the form of random access memory (RAM), one or more hard drives 624, and/or one or more drives that handle removable media 626 such as compact disks (CD), flash memory cards, digital video disk (DVD), and the like.

The electronic apparatus 600 may also include a display device 616, one or more speakers 618, and a keyboard and/or controller 630, which can include a mouse, trackball, touch screen, voice-recognition device, or any other device that permits a system user to input information into and receive information from the electronic apparatus 600.

More details and optional aspects of FIG. 11 may be described in connection with examples described above (e.g., FIGS. 1A to 10) or below (e.g., FIG. 12).

FIG. 12 illustrates a computing device in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations, the at least one communication chip 706 is also physically and electrically coupled to the board 702. In further implementations, the communication chip 706 is part of the processor 704. Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter-range wireless communications such as Wi-Fi and Bluetooth and a second communication chip 706 may be dedicated to longer-range wireless communications such as GPS, EDGE, GPRS, CDMA, WiMAX, LTE, Ev-DO, and others. The processor 704 of the computing device 700 includes an integrated circuit die packaged within the processor 704. In some implementations of the invention, the integrated circuit die of the processor includes one or more devices that are assembled in an ePLB or cWLB-based POP package that includes a mold layer directly contacting a substrate, in accordance with implementations of the invention. The term “processor” may refer to any device or portion of a device that processes electronic data from registers and/or memory to transform that electronic data into other electronic data that may be stored in registers and/or memory. The communication chip 706 also includes an integrated circuit die packaged within the communication chip 706. In accordance with another implementation of the invention, the integrated circuit die of the communication chip includes one or more devices that are assembled in an ePLB or eWLB-based POP package that includes a mold layer directly contacting a substrate, in accordance with implementations of the invention.

More details and optional aspects of FIG. 12 may be described in connection with examples described above (e.g., FIGS. 1A to 12) or below.

It is further understood that the disclosure of several steps, processes, operations, or functions disclosed in the description or claims shall not be construed to imply that these operations are necessarily dependent on the order described unless explicitly stated in the individual case or necessary for technical reasons. Therefore, the previous description does not limit the execution of several steps or functions to a certain order. Furthermore, in further examples, a single step, function, process, or operation may include and/or be broken up into several sub-steps, -functions, -processes, or -operations.

If some aspects have been described in relation to a device or system, these aspects should also be understood as a description of the corresponding method. For example, a block, device, or functional aspect of the device or system may correspond to a feature, such as a method step, of the corresponding method. Accordingly, aspects described in relation to a method shall also be understood as a description of a corresponding block, a corresponding element, a property, or a functional feature of a corresponding device or a corresponding system.

An example (e.g. example 1) is a cooling system for a computing system comprising a plurality of electronic components, the cooling system comprising: a two-phase coolant having a saturation temperature and a closed loop for the two-phase coolant. The closed loop comprising: a valve fluidly connected between an outlet of a heat exchanger and an inlet of a plurality of evaporator structures configured to be thermally coupled to the plurality of electronic components, a compressor fluidly connected between an outlet of the plurality of evaporator structures and an inlet of the heat exchanger, and processing circuitry. Wherein the processing circuitry is configured to: monitor one or more system temperatures of the computing system and adjust an operation of at least one of the valve or the compressor to alter the saturation temperature based on the one or more system temperatures.

Another example (e.g. example 2) relates to a previously described example (e.g. example 1), wherein the processor adjusts the valve and/or the compressor based on a thermodynamic information for the two-phase coolant.

Another example (e.g. example 3) relates to a previously described example (e.g. example 2), wherein the processor determines the thermodynamic information for the two-phase coolant.

Another example (e.g. example 4) relates to a previously described example (e.g. examples 2 or 3), further comprising a memory in communication with the processor, wherein the memory stores the thermodynamic information for the two-phase coolant, wherein the processor tunes the valve and/or the compressor based on the stored thermodynamic information.

Another example (e.g. example 5) relates to a previously described example (e.g. one of the examples 1-4), further comprising receiving the one or more system temperatures from a motherboard.

Another example (e.g. example 6) relates to a previously described example (e.g. one of the examples 1-5), further comprising one or more temperature sensors providing the one or more system temperatures, wherein the one or more temperature sensors are located at least one of a vapor line, a liquid line, a reservoir, the inlets of the plurality of cold plates, or the outlets of the plurality of cold plates.

Another example (e.g. example 7) relates to a previously described example (e.g. one of the examples 1-6), wherein the one or more system temperatures comprise a case temperature.

Another example (e.g. example 8) relates to a previously described example (e.g. one of the examples 1-7), wherein the processor monitors a plurality of system pressures and adjusts the valve and/or the compressor to alter the saturation temperature based on the plurality of system pressures.

Another example (e.g. example 9) relates to a previously described example (e.g. example 8), further comprising pressure sensors providing the plurality of system pressures, wherein the pressure sensors are located at least before an inlet of the valve and after an outlet of the valve.

Another example (e.g. example 10) relates to a previously described example (e.g. example 9), wherein the pressure sensors are further located at the inlets of the plurality of cold plates and the outlets of the plurality of evaporator structures.

Another example (e.g. example 11) relates to a previously described example (e.g. one of the examples 1-10), wherein the processor adjusts the valve and/or the compressor to keep a hottest electronic device temperature within a threshold range.

Another example (e.g. example 12) relates to a previously described example (e.g. one of the examples 1-11), wherein the plurality of evaporator structures are fluidly connected in parallel.

Another example (e.g. example 13) relates to a previously described example (e.g. one of the examples 1-12), wherein the plurality of evaporator structures are fluidly connected in series.

Another example (e.g. example 14) relates to a previously described example (e.g. one of the examples 1-13), further comprising an external interface connected to the processor.

Another example (e.g. example 15) relates to a previously described example (e.g. example 14), wherein the processor adjusts the valve and/or the compressor further based on an input from the external interface.

Another example (e.g. example 16) relates to a previously described example (e.g. one of the examples 1-15), wherein the evaporator structures are cold plates.

Another example (e.g. example 17) relates to a previously described example (e.g. one of the examples 1-16), wherein the computer system is a client device.

Another example (e.g. example 18) relates to a previously described example (e.g. one of the examples 1-17), wherein the computer system comprises a maximum power dissipation of 1 kW.

Another example (e.g. example 19) relates to a previously described example (e.g. one of the examples 1-18), wherein the two-phase coolant is a low-GWP refrigerant.

Another example (e.g. example 20) relates to a previously described example (e.g. one of the examples 1-19), wherein the processing circuitry is configured to adjust an operation of at least one of the valve or the compressor according to an eco-friendly threshold.

An example (e.g. example 21) is a control system for a cooling system comprising interface circuitry, instructions stored on a non-transitory, machine-readable medium, and processor circuitry to execute the machine-readable instructions. The instructions causing the processing circuitry to: monitor one or more system temperatures and adjust a valve and/or a compressor of the cooling system to alter a saturation temperature of a two-phase coolant based on the one or more system temperatures.

An example (e.g. example 22) is a method for cooling a plurality of electronic components with a cooling system. Wherein the cooling system comprises: a two-phase coolant having a saturation temperature and a closed loop for the two-phase coolant. The closed loop comprising a valve fluidly connected between an outlet of a heat exchanger and an inlet of a plurality of evaporator structures, wherein each of the plurality of evaporator structures are thermally coupled to the plurality of electronic components, and a compressor fluidly connected between an outlet of the plurality of evaporator structures and an inlet of the heat exchanger. The method comprising: monitoring one or more system temperatures and adjusting the valve and/or the compressor to alter the saturation temperature based on the one or more system temperatures.

Another example (e.g. example 23) relates to a previously described example (e.g. example 22), wherein adjusting the valve and/or compressor comprises increasing pressure to increase the saturation temperature and decreasing pressure to lower saturation temperature.

Another example (e.g. example 24) relates to a previously described example (e.g. example 23), wherein increasing pressure comprises constricting an opening of the valve and decreasing pressure comprises expanding the opening of the valve.

An example (e.g. example 25) is a non-transitory, computer-readable medium comprising a program code that, when the program code is executed on a processor, a computer, or a programmable hardware component, causes the processor, computer, or programmable hardware component to perform the method of a previously described example (e.g. one of the examples 22-24)

The disclosed methods, apparatuses, and systems are not to be construed as limiting in any way. Instead, the present disclosure is directed toward all novel and nonobvious features and aspects of the various disclosed examples, alone and in various combinations and sub-combinations with one another. The disclosed methods, apparatuses, and systems are not limited to any specific aspect or feature or combination thereof, nor do the disclosed examples require that any one or more specific advantages be present, or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. A cooling system for a computing system comprising a plurality of electronic components, the cooling system comprising:
a two-phase coolant having a saturation temperature,
a closed loop for the two-phase coolant, the closed loop comprising:
a valve fluidly connected between an outlet of a heat exchanger and an inlet of a plurality of evaporator structures configured to be thermally coupled to the plurality of electronic components; and
a compressor fluidly connected between an outlet of the plurality of evaporator structures and an inlet of the heat exchanger, and
processing circuitry, wherein the processing circuitry is configured to:
monitor one or more system temperatures of the computing system; and
adjust an operation of at least one of the valve or the compressor to alter the saturation temperature based on the one or more system temperatures.

2. The cooling system of claim 1, wherein the processor adjusts the valve and/or the compressor based on a thermodynamic information for the two-phase coolant.

3. The cooling system of claim 2, wherein the processor determines the thermodynamic information for the two-phase coolant.

4. The cooling system of claim 2, further comprising a memory in communication with the processor, wherein the memory stores the thermodynamic information for the two-phase coolant, wherein the processor tunes the valve and/or the compressor based on the stored thermodynamic information.

5. The cooling system of claim 1, further comprising receiving the one or more system temperatures from a motherboard.

6. The cooling system of claim 1, further comprising one or more temperature sensors providing the one or more system temperatures, wherein the one or more temperature sensors are located at least one of a vapor line, a liquid line, a reservoir, the inlets of the plurality of cold plates, or the outlets of the plurality of cold plates.

7. The cooling system of claim 1, wherein the one or more system temperatures comprise a case temperature.

8. The cooling system of claim 1, wherein the processor monitors a plurality of system pressures and adjusts the valve and/or the compressor to alter the saturation temperature based on the plurality of system pressures.

9. The cooling system of claim 8, further comprising pressure sensors providing the plurality of system pressures, wherein the pressure sensors are located at least before an inlet of the valve and after an outlet of the valve.

10. The cooling system of claim 9, wherein the pressure sensors are further located at the inlets of the plurality of cold plates and the outlets of the plurality of evaporator structures.

11. The cooling system of claim 1, wherein the processor adjusts the valve and/or the compressor to keep a hottest electronic device temperature within a threshold range.

12. The cooling system of claim 1, wherein the plurality of evaporator structures are fluidly connected in parallel.

13. The cooling system of claim 1, wherein the plurality of evaporator structures are fluidly connected in series.

14. The cooling system of claim 1, further comprising an external interface connected to the processor, wherein the processor adjusts the valve and/or the compressor further based on an input from the external interface.

15. The cooling system of claim 1, wherein the evaporator structures are cold plates.

16. The cooling system of claim 1, wherein the computer system is a client device.

17. The cooling system of claim 1, wherein the two-phase coolant is a low-GWP refrigerant.

18. The cooling system of claim 1, wherein the processing circuitry is configured to adjust an operation of at least one of the valve or the compressor according to an eco-friendly threshold.

19. A control system for a cooling system comprising interface circuitry, instructions stored on a non-transitory, machine-readable medium, and processor circuitry to execute the machine-readable instructions to:
monitor one or more system temperatures; and
adjust a valve and/or a compressor of the cooling system to alter a saturation temperature of a two-phase coolant based on the one or more system temperatures.

20. A method for cooling a plurality of electronic components with a cooling system, wherein the cooling system comprises:
a two-phase coolant having a saturation temperature,
a closed loop for the two-phase coolant, the closed loop comprising:
a valve fluidly connected between an outlet of a heat exchanger and an inlet of a plurality of evaporator structures, wherein each of the plurality of evaporator structures are thermally coupled to the plurality of electronic components; and
a compressor fluidly connected between an outlet of the plurality of evaporator structures and an inlet of the heat exchanger, and
the method comprising:
monitoring one or more system temperatures; and
adjusting the valve and/or the compressor to alter the saturation temperature based on the one or more system temperatures.
